(19) United States
(12) Patent Application Publication
(10) Pub. No.: US 2008/0230120 A1
(43) Pub. Date: Sep. 25, 2008

(54) Photovoltaic device with nanostructured layers

(75) Inventor: Damoder Reddy, Los Gatos, CA (US)

Correspondence Address: MORGAN, LEWIS & BOCKIUS, LLP, ONE MARKET SPEAR STREET TOWER, SAN FRANCISCO, CA, 94105, US

(73) Assignee: Solexant Corp., Sunnyvale, CA (US)

(21) Appl. No.: 11/708,072

(22) Filed: Feb. 12, 2007

Related U.S. Application Data
(60) Provisional application No. 60/772,548, filed on Feb. 13, 2006.
(60) Provisional application No. 60/796,820, filed on May 2, 2006.

(51) Int. Cl. H01L 31/04; H01L 31/028; H01L 31/0296; H01L 31/0304

(52) U.S. Cl. 136/260; 136/252; 136/264; 136/265; 136/261; 136/263; 136/262; 977/750; 977/762; 977/811

(57) ABSTRACT

Photovoltaic devices or solar cells are provided. More particularly, the present invention provides photovoltaic devices having IR and/or UV absorbing nanostructured layers that increase efficiency of solar cells. In some embodiments the nanostructured materials are integrated with one or more of: crystalline silicon (single crystal or polycrystalline) solar cells and thin film (amorphous silicon, microcrystalline silicon, CdTe, CIGS and III-V materials) solar cells whose absorption is primarily in the visible region. In some embodiments the nanoparticle materials are comprised of quantum dots, rods or multipods of various sizes.

### RELATED APPLICATIONS

This patent application claims the benefit of, and priority to, U.S. Provisional Patent Application Ser. No. 60/772,548, filed on Feb. 13, 2006, titled “Solar Cells Integrated With IR and UV Absorbing Nanoparticle Layers,” and U.S. Provisional Patent Application Ser. No. 60/796,820, filed on May 2, 2006, titled “Nanocomposite Solar Cell,” the disclosures of both of which are hereby incorporated by reference in their entirety.

### FIELD OF THE INVENTION

In general, the present invention relates to the field of photovoltaics or solar cells. More particularly, the present invention relates to photovoltaic devices having nanostructured layers.

### BACKGROUND OF THE INVENTION

Increasing oil prices have heightened the importance of developing cost effective renewable energy. Significant efforts are underway around the world to develop cost effective solar cells to harvest solar energy. Current solar energy technologies can be broadly categorized as crystalline silicon and thin film technologies. More than 90% of the solar cells are made from silicon—single crystal silicon, polycrystalline silicon or amorphous silicon.

Historically, crystalline silicon (c-Si) has been used as the light-absorbing semiconductor in most solar cells, even though it is a relatively poor absorber of light and requires a considerable thickness (several hundred microns) of material. Nevertheless, it has proved convenient because it yields stable solar cells with good efficiencies (12-20%, half to two-thirds of the theoretical maximum) and uses process technology developed from the knowledge base of the microelectronics industry.

Two types of crystalline silicon are used in the industry. The first is monocrystalline, produced by slicing wafers (approximately 150 mm diameter and 350 microns thick) from a high-purity single crystal boule. The second is multicrystalline silicon, made by sawing a cast block of silicon first into bars and then wafers. The main trend in crystalline silicon cell manufacture is toward multicrystalline technology.

For both mono- and multicrystalline Si, a semiconductor p-n junction is formed by diffusing phosphorus (an n-type dopant) into the top surface of the boron doped (p-type) Si wafer. Screen-printed contacts are applied to the front and rear of the cell, with the front contact pattern specially designed to allow maximum light exposure of the Si material with minimum electrical (resistive) losses in the cell.

Silicon solar cells are very expensive. Manufacturing is mature and not amenable for significant cost reduction. Silicon is not an ideal material for use in solar cells as it primarily absorbs in the visible region of the solar spectrum as illustrated in FIG. 1. Significant amount of solar radiation comprises of IR photons as shown in FIG. 2. These IR photons are not harvested by silicon solar cells thereby limiting their conversion efficiency.

Second generation solar cell technology is based on thin films. Two main thin film technologies are Amorphous Silicon as shown in FIG. 3 and Copper Indium Gallium Diselenide (CIGS).

Amorphous silicon (a-Si) was viewed as the “only” thin film PV material in the 1980s. But by the end of that decade, and in the early 1990s, it was dismissed by many observers for its low efficiencies and instability. However, amorphous silicon technology has made good progress toward developing a very sophisticated solution to these problems: multijunction configurations. Now, commercial, multijunction a-Si modules could be in the 7%-9% efficiency range. United Solar and Kaneka have built 25 MW facilities and several companies have announced plans to build manufacturing plants in Japan and Germany.

The key obstacles to a-Si technology are low efficiencies (about 10% stable), light-induced efficiency degradation (which requires more complicated cell designs such as multiple junctions), and process costs (fabrication methods are vacuum-based and fairly slow). All of these issues are important to the potential of manufacturing cost-effective a-Si modules.

Amorphous silicon solar cells also have poor IR absorption and do not harvest energy from IR photons of the solar spectrum. Microcrystalline silicon extends absorption into longer wavelengths but also has poor absorption in the IR region. A variety of reflector designs have been employed to increase IR harvesting in amorphous silicon solar cells. These reflectors add significant cost but provide limited benefit, as they are unable to extend the IR absorption of amorphous silicon beyond 1,000 nm. Significant efficiency improvement can be achieved if IR absorbing layers can be developed which can be cost effectively integrated with amorphous and microcrystalline silicon solar cells.

Thin film solar cells made from Copper Indium Gallium Diselenide (CIGS) absorbers show promise in achieving high conversion efficiencies of 10-12%. The record high efficiency of CIGS solar cells (19.2% NREL) is by far the highest compared with those achieved by other thin film technologies such as Cadmium Telluride (CdTe) or amorphous Silicon (a-Si).

These record breaking small area devices have been fabricated using vacuum evaporation techniques which are capital intensive and quite costly. It is very challenging to fabricate CIGS films of uniform composition on large area substrates. This limitation also affects the process yield, which are generally quite low. Because of these limitations, implementation of production techniques has not been successful for large-scale, low-cost commercial production of thin film solar cells and modules and is non-competitive with today's crystalline silicon solar modules.

To overcome the limitations of the physical vapor deposition techniques that use expensive vacuum equipment, several companies have been developing high throughput vacuum processes (ex: DayStar, Global Solar) and non-vacuum processes (ex: ISET, Nanosolar) for the fabrication of CIGS solar cells. Using ink technology, very high active materials utilization can be achieved with relatively low capital equipment costs. The combined effect is a low-cost manufacturing process for thin film solar devices. CIGS can be made on flexible substrates making it possible to reduce the weight of solar cells. Cost of CIGS solar cells is expected to be lower than crystalline silicon making them competitive even at lower efficiencies. Two main problems with CIGS solar cells are: (1) there is no clear pathway to higher efficiency and (2) high processing temperatures make it difficult to use high speed roll to roll process and hence they will not be able to achieve significantly lower cost structure achievable by amorphous silicon solar cells.

CIGS solar cells also have poor IR absorption and do not absorb or harvest energy from IR photons of the solar spectrum. Efficiency improvement can be achieved if IR absorbing layers can be developed which can be cost effectively integrated with CIGS solar cells.

There are significant problems with the currently available technologies. For example, crystalline silicon solar cells which have >90% market share today are very expensive. Solar energy with c-silicon solar cells costs about 25 cents per kwh as compared to <10 cents per kwh for fossil fuels. In addition, the capital cost of installing solar panels is extremely high limiting its adoption rate. Crystalline solar cell technology is mature and unlikely to improve performance or cost competitiveness in near future. Amorphous silicon thin film technology is amenable to high volume manufacturing that could lead to low cost solar cells. However, amorphous and microcrystal silicon solar cells absorb only in the visible region and do not harvest any photons in the IR region.

A number of examples exist in the prior art in combining such IR absorbing thin film layers with Silicon layers to increase solar energy conversion efficiency. IR absorbing thin film layers used in the literature were deposited through expensive vacuum deposition process. Examples in the literature include multijunction cells and tandem cells. Examples in the literature include (1) four terminal devices made from two separate cells and (2) two terminal devices made by incorporating tunnel junctions. All these examples known in the literature are very expensive to produce limiting their commercial applications.

The National Renewable Energy Lab (NREL) has initiated a high efficiency tandem solar cell program in 2001 with the primary aim of achieving high efficiencies. A number of semiconductor materials such as SiGe, PbSe, PbS and III-V materials absorb in the IR region and can be used to harvest IR photons. Researchers at NREL have demonstrated that broadband multijunction solar cells can be prepared by stacking cells with absorption in different wavelength ranges. Tandem solar cells use multiple materials with different bandgaps in series in a single cell. Significant progress has been made in building tandem solar cells however many limitations remain. It is unlikely that these tandem cells will ever achieve cost competitiveness for commercial applications. These multijunction tandem cells are extremely complicated to design (due to current balancing requirements) and tend to be quite expensive. Hence these tandem cells are limited for use in defense, space and terrestrial applications where cost is not a critical driving factor. However, it is unlikely that such designs can ever be economical enough to be used for commercial solar cell applications.

Next generation solar cell designs required to truly achieve high efficiencies with light weight and low cost. Two potential candidates are (1) polymer solar cells and (2) nanoparticle solar cells. Polymer solar cells have the potential to be low cost due to roll to roll processing at moderate temperatures (<150 C). However, polymers suffer from two main drawbacks: (1) poor efficiencies due slow charge transport and (2) poor stability—especially to UV. Hence it is unlikely that polymer solar cells will be able to achieve the required performance to become the next generation solar cell.

Several research groups have been conducting experimental studies on quantum dot based solar cells. Best efficiencies reported to date have been <5%. Main reasons for low efficiencies of these nanoparticle solar cells has been charge recombination due to (1) surface charges on the nano particles and (2) poor charge transport in the polymer host. Novel synthetic methods need to be developed to prepare quantum dots without surface charge effects. To reduce the impact of polymer host on the charge transport quantum rods with a large aspect ratio have been suggested. Researchers from University of California Berkeley have shown that better efficiency can be achieved by using quantum rods with >10:1 aspect ratio.

IR absorbing nanoparticles have been reported by University of Toronto and University of Buffalo. Ted Sargent's team at University of Toronto has made the infrared photovoltaics based on solution-processing by suspending lead sulfide semiconducting nanocrystals, measuring 4 nanometers (nm) in diameter, in a semiconducting plastic (Nature Materials 2005, 4, 138-142). The 4-nm spheres of PbS are smaller than the radius of an excited electron's orbit. The effect of this so-called quantum confinement is that the light wavelengths at which the quantum dots begin to absorb energy are directly related to the crystals' size. This means that by changing the size of the nanocrystals, plastic solar cell can be tuned to any wavelengths desired, from the IR to the visible spectrum. By controlling the size of the nanocrystals solar cells can be tuned to absorb IR light at wavelengths of 980, 1200, and 1355 run and turn it into electric current. IR photovoltaics have greater potential because half of the energy in sunlight occurs in the IR, at wavelengths ranging from 700 nm to 2 microns. Sargent's first IR system has an abysmal-sounding power-conversion efficiency of 0.001%.

Efficient IR absorbing Quantum Dot Photovoltaics composed of indium phosphide (InP) nanocrystals were developed by Paras Prasad's team at University of Buffalo (UB). InP quantum dots demonstrated luminescence efficiencies comparable to other quantum dots, but they also emit light in longer wavelengths in the red region of the spectrum. This is a key advantage because red-light emission means these quantum dots will be capable of harvesting photons in the IR region. Quantum dots, comprised of cadmium selenide, emit mostly in the lower visible wavelength range. Silicon solar cells act primarily in the green region, thus capturing only a fraction of the available light energy. By contrast, lead selenide quantum dots can absorb in the infrared, allowing for the development of photovoltaic cells that can efficiently convert many times more light to usable energy than can current silicon solar cells. UB group demonstrated 3% quantum efficiency for the InP quantum dots. Their work was described in the paper, “Efficient photoconductive devices at infrared wavelengths using quantum dot-polymer nanocomposites,” published online Aug. 11, 2005 in Applied Physics Letters.

Accordingly, many challenges remain and there is significant need for further developments.

### SUMMARY OF THE INVENTION

Embodiments of the present invention generally relate to the field of photovoltaics or solar cells. More particularly, the present invention provides photovoltaic devices having IR and/or UV absorbing nanostructured layers.

In one aspect, embodiments of the present invention provide a photovoltaic device, comprising: a first photoactive layer comprised of a semiconductor material exhibiting absorption of radiation substantially in a visible region of the solar spectrum, and a second photoactive layer comprised of nanostructured material exhibiting absorption of radiation substantially in an IR region of the solar spectrum. A recombination layer is disposed between the first and second layers, and configured to promote charge transport between the first and second layers.

In another aspect, the present invention provides a photovoltaic device, comprising: a first photoactive layer; a top photoactive layer disposed above the first layer, said top photoactive layer comprised of a material exhibiting a bandgap greater than the band gap of the first layer; and a bottom photoactive layer disposed below the first layer, said bottom photoactive layer comprised of a material exhibiting a bandgap lower than the band gap of the first layer. In some embodiments, the top photoactive layer exhibits a bandgap of 2 ev and greater, and the bottom photoactive layer exhibits a bandgap of 1.2 ev and lower.

In yet another aspect, embodiments of the present invention provide a photovoltaic device comprising: a first photoactive layer comprised of a semiconductor material exhibiting absorption of radiation substantially in a visible region of the solar spectrum and a top photoactive layer comprised of one or more nanoparticles exhibiting absorption of radiation substantially in an UV region of the solar spectrum. A recombination layer is disposed between the first and top layers, and configured to promote charge transport between the first and top layers.

In a further aspect, embodiments of the present invention provides a photovoltaic device, comprising: a first photoactive layer comprised of semiconductor material exhibiting absorption of radiation substantially in a visible region of the solar spectrum, and a top photoactive layer comprised of nanostructured material exhibiting absorption of radiation substantially in an UV region of the solar spectrum formed above the first layer. A recombination layer is disposed between the first and top layers, and configured to promote charge transport between the first and top layers. A bottom photoactive layer comprised of nanostructured material exhibiting absorption of radiation substantially in an IR region of the solar spectrum is formed below the first photoactive layer. A second recombination layer is disposed between the first and bottom layers, and configured to promote charge transport between the first and bottom layers.

The nanostructured material is any suitable material that comprises nano-sized materials or particles. These nano-sized materials or particles may be dispersed in another material, such as a precursor or carrier compound. For example, in some embodiments the nanostructured material is a nanocomposite material which comprises hole conducting or electron conducting polymers and complimentary nanoparticles dispersed therein. The nanocomposite material may be comprised of one or more nanoparticles dispersed in a polymer. In other embodiments, the nanostructured material is comprised of any one or more of: semiconducting dots, rods or multipods. Multipods may comprise bi, and tri rod structures, or other 2 and 3 dimensional structures. Examples of suitable nanoparticles materials include, but are not limited to, any one or more of: PbSe, PbS, CdHgTe, Si or SiGe. Of particular advantage, the size and/or composition of the nanoparticles may be selected to provide a range of radiation absorption, thus increasing the absorption efficiency of the device.

In other embodiments, the nanostructured material is comprised of a mixture of photosensitive nanoparticles and conductive nanoparticles. One or both of the photosensitive and conductive nanoparticles may be functionalized. Examples of conductive nanoparticles include, but are not limited to, any one or more of: single wall carbon nanotubes (SWCNT), TiO₂ nanotubes, or ZnO nanowires. Examples of photosensitive nanoparticles include, but are not limited to, any one or more of: CdSe, ZnSe, PbSe, InP, Si, Ge, SiGe, or Group III-V materials.

In some embodiments, the recombination layer may be comprised of a doped layer comprised of a material that conducts charge opposite that of the nanostructured material. Thus in some embodiments, the recombination layer will include a doped layer with a charge opposite that of a conducting polymer in the nanostructured material. Alternatively, the recombination layer is a doped layer comprised of a material that conducts charge opposite that of the nanoparticles in the nanostructured material. The recombination layer may further comprise a metal layer and/or an insulator layer coupled to a doped layer.

The first photoactive layer may be comprised of any one of: amorphous silicon, single-crystalline silicon, poly-crystalline silicon, microcrystalline silicon, nanocrystalline silicon, CdTe, cooper indium gallium diselinide (CIGS), or Group III-V semiconductor material. In another embodiment the first photoactive layer is comprised of an organic material which is hole conducting or electron conducting. For example, the first photoactive layer may be comprised of a P-I-N semiconductor or a P-N semiconductor. In alternative embodiment, first photoactive layer is comprised on any one or more of: P3HT, P3OT, MEH-PPV, PCBM, CuPe, PCTBI or C60.

In one exemplary embodiment the second layer comprised of nanostructured material comprises one or more inorganic nanoparticles dispersed in a hole conducting polymer, and the recombination layer is comprised of an N+ doped layer; and a metal layer coupled to said N+ doped layer.

### BRIEF DESCRIPTION OF THE FIGURES

The foregoing and other aspects of the present invention will be apparent upon consideration of the following detailed description, taken in conjunction with the accompanying drawings, in which like reference characters refer to like parts throughout, and in which:

FIG. 1 shows the known absorption spectrum of Amorphous silicon;

FIG. 2 illustrates the known absorption spectrum of Microcrystalline silicon;

FIG. 3 shows a conventional amorphous silicon solar cell design;

FIG. 4 is a schematic representation of Core-Shell quantum dots (Examples: PbSe, PbS and InP);

FIG. 5 illustrates Quantum dots (QD) of different size absorb and emit at different colors according to embodiments of the present invention;

FIG. 6 illustrates nanoparticles capped with solvents such as tr-n-octyl phosphine oxide (TOPO);

FIG. 7 shows functionalized Nanoparticles prepared according to embodiments of the present invention;

FIG. 8 is a schematic drawing showing one embodiment of a photovoltaic device of the present invention with IR absorbing or harvesting nanoparticle layers integrated with amorphous or microcrystalline silicon layers;

FIG. 9 is a schematic diagram illustrating one embodiment of the recombination layer of the present invention;

FIG. 10 illustrates a schematic drawing showing another embodiment of a photovoltaic device of the present invention with IR harvesting nanoparticle layers integrated with polycrystalline or single crystal silicon layers;

FIG. 11 shows a photovoltaic device having IR harvesting nanoparticle layers integrated with CdTe layers according to embodiments of the present invention;

FIG. 12 depicts a photovoltaic device with IR harvesting nanoparticle layers integrated with CIGS layers according to embodiments of the present invention;

FIG. 13 shows a schematic drawing showing one embodiment of a photovoltaic device of the present invention with UV absorbing or harvesting nanoparticle layers integrated with amorphous or microcrystalline silicon layers;

FIG. 14 is a schematic drawing showing one embodiment of a photovoltaic device of the present invention with UV harvesting nanoparticle layers integrated with polycrystalline silicon or single crystal silicon layers;

FIG. 15 depicts a schematic drawing showing one embodiment of a photovoltaic device of the present invention with UV harvesting nanoparticle layers integrated with CdTe layers;

FIG. 16 illustrates a schematic drawing showing one embodiment of a photovoltaic device of the present invention with UV harvesting nanoparticle layers integrated with CIGS layers;

FIG. 17 shows a photovoltaic device with UV & IR absorbing or harvesting nanoparticle layers integrated with amorphous or microcrystalline silicon layers according to embodiments of the present invention;

FIG. 18 illustrates a photovoltaic device with UV & IR harvesting nanoparticle layers are integrated with polycrystalline or single crystal silicon layers according to embodiments of the present invention;

FIG. 19 shows UV & IR harvesting nanoparticle layers integrated with CdTe layers according to embodiments of the present invention;

FIG. 20 shows UV & IR harvesting nanoparticle layers are integrated with CIGS layers according to embodiments of the present invention;

FIG. 21 illustrates another embodiment of a photovoltaic device of the present invention having UV harvesting nanoparticle layers integrated with III-V semiconductor layers;

FIG. 22 illustrates a four junction crystalline silicon solar cell integrated with IR harvesting nanoparticles according to embodiments of the present invention;

FIG. 23 shows a four junction crystalline silicon solar cell integrated with UV harvesting nanoparticles according to embodiments of the present invention;

FIG. 24 shows a four junction thin film solar cell integrated with IR harvesting nanoparticles according to embodiments of the present invention;

FIG. 25 depicts a four junction thin film solar cell integrated with UV harvesting nanoparticles according to embodiments of the present invention;

FIG. 26 shows a schematic drawing of a nanocomposite photovoltaic device with light harvesting layer of photosensitive nanoparticles dispersed in a polymer precursor according to embodiments of the present invention;

FIG. 27 shows a schematic drawing of a nanocomposite photovoltaic device with light harvesting layer of photosensitive nanoparticles dispersed in a mixture of polymer and polymer precursor according to embodiments of the present invention;

FIG. 28 depicts a schematic drawing of a nanocomposite photovoltaic device with light harvesting layer of photosensitive nanoparticle sensitized carbon nanotubes (SWCNT) dispersed in a polymer precursor according to embodiments of the present invention;

FIG. 29 illustrates a nanocomposite photovoltaic device with light harvesting layer of photosensitive nanoparticle sensitized carbon nanotubes (SWCNT) dispersed in a mixture of polymer and polymer precursor according to embodiments of the present invention;

FIG. 30 shows a nanocomposite photovoltaic device having light harvesting layer of photosensitive nanoparticles and conducting nanostructures such as SWCNT dispersed in a mixture of polymer and polymer precursor according to embodiments of the present invention;

FIG. 31 shows a nanocomposite photovoltaic device with light harvesting layer of photosensitive nanoparticles and conducting nanostructures such as SWCNT dispersed in a mixture of polymer and polymer precursor according to embodiments of the present invention; and

FIG. 32 is a process flow diagram showing methods for preparing photovoltaic devices with a light harvesting layer containing a polymerizable precursor according to embodiments of the present invention.

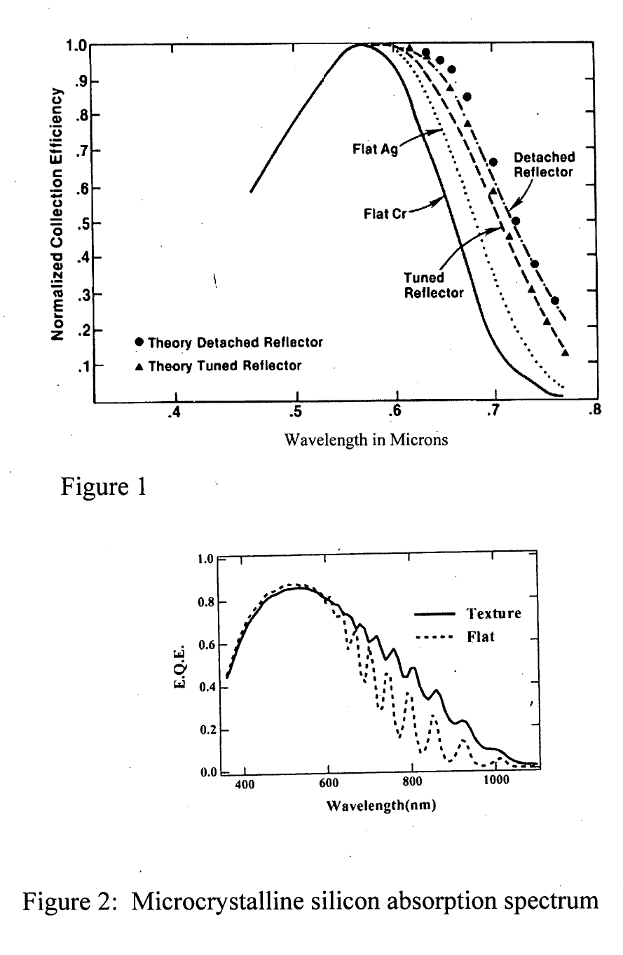

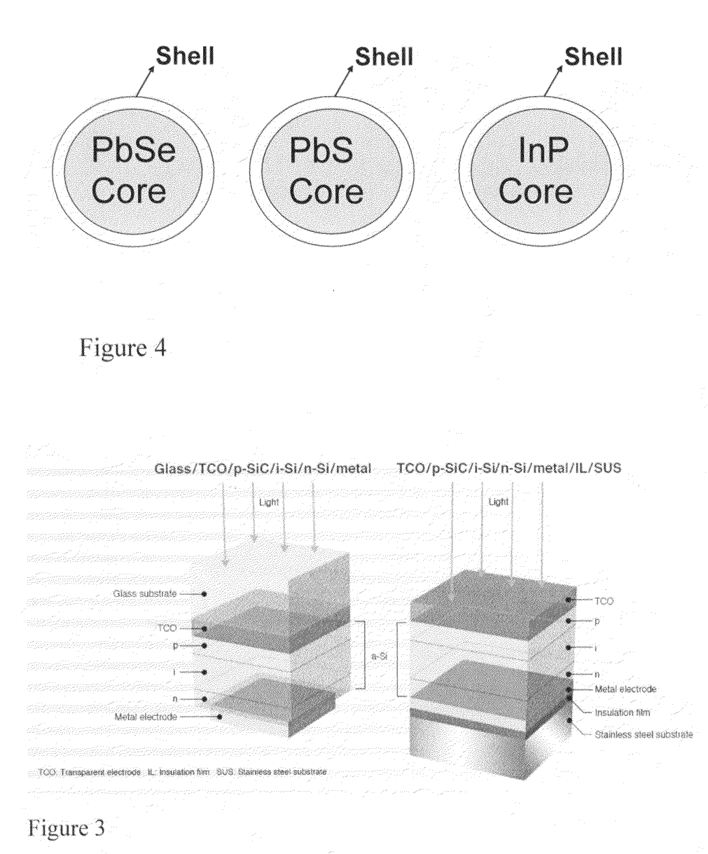

### DETAILED DESCRIPTION OF THE INVENTION

Embodiments of the present invention generally relate to the field of photovoltaic or solar cells. More particularly, the present invention provides photovoltaic devices having IR and/or UV absorbing nanostructured layers. The terms photovoltaic device and solar cell(s) may be used interchangeably throughout the description.

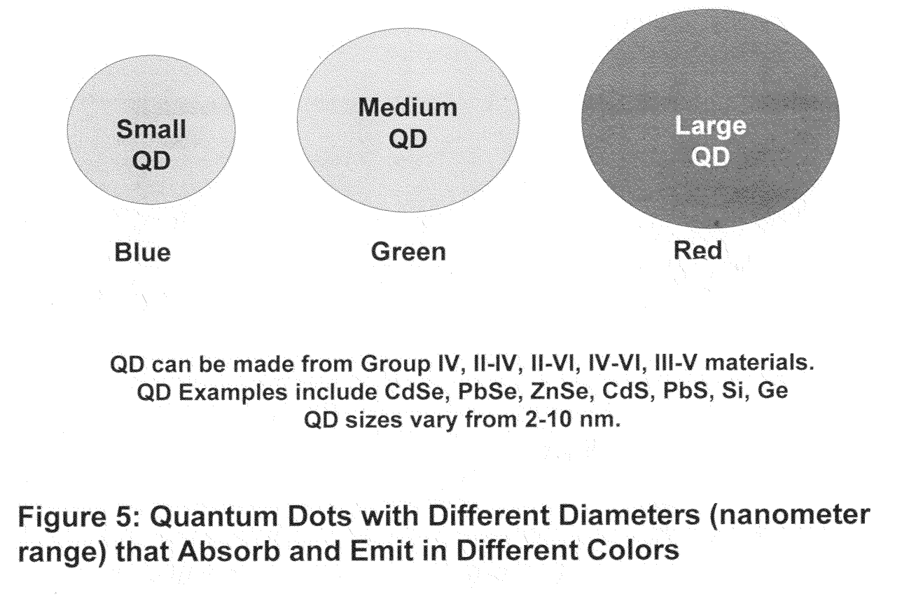

Present invention further relates to increasing solar cell efficiency cost effectively by integrating IR photon absorbing or harvesting and/or UV photon absorbing or harvesting nanostructure materials. In some embodiments the nanostructured materials are integrated with one or more of: crystalline silicon (single crystal or polycrystalline) solar cells and thin film (amorphous silicon, microcrystalline silicon, CdTe, CIGS and III-V materials) solar cells whose absorption is primarily in the visible region. In some embodiments, the nanostructured materials are comprised of one or more nanoparticles integrated with a first layer of material which exhibits absorption of radiation substantially in the visible spectrum. In some embodiments the nanoparticle layer is comprised of quantum dots, rods or multipods of various sizes. In one example nanoparticles are sized in the range of approximately 2 nm to 10 nm, and more typically in the range of approximately 2 nm to 6 nm, as shown in FIG. 5. Small nanoparticles absorb at the blue end of the spectrum while the large size nanoparticles absorb in the red end of the spectrum.

Nanoparticle layers are preferably comprised of various luminescent materials. Examples of suitable materials include, but are not limited to, any one or more of CdSe, PbSe, ZnSe, CdS, PbS, Si, Ge, SiGe, InP, or III-V semiconductors. PbS, PbSe and SiGe are examples of IR absorbing nanoparticles. ZnSe is an example of UV absorbing nanoparticle. IR absorbing and UV absorbing nanoparticles of various chemistry and particle sizes can be prepared by following methods known in the art.

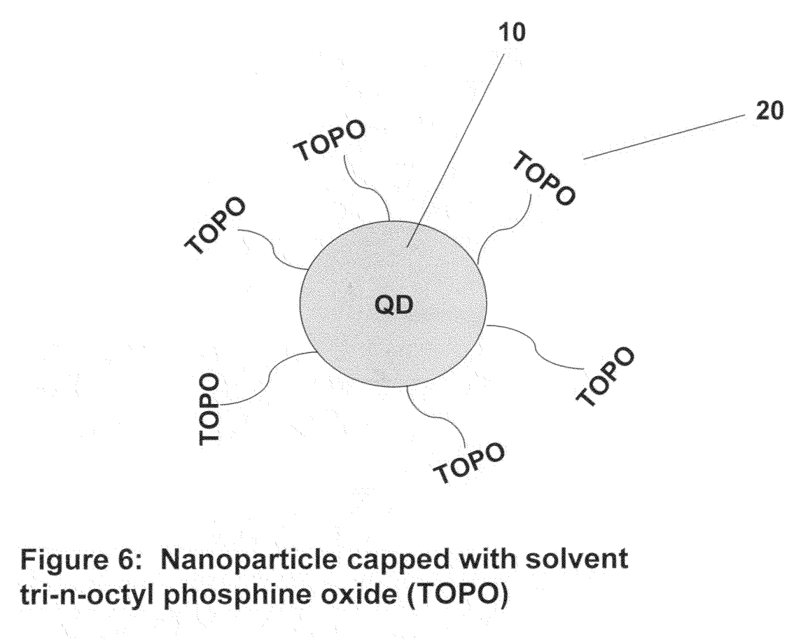

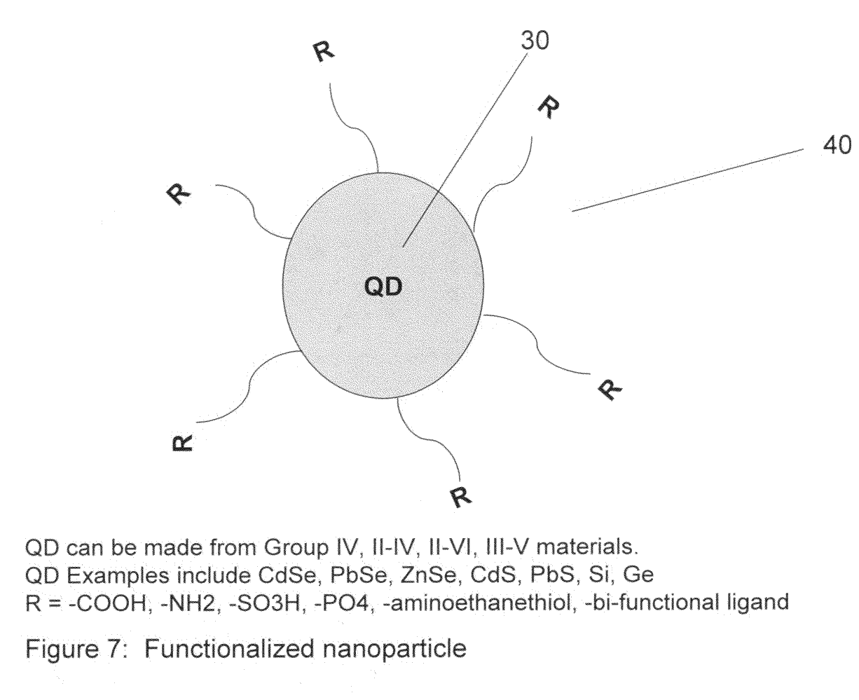

In an alternative embodiment, the nanostructured layer(s) are comprised of a polymer composite obtained by dispersing nanoparticles in a conducting polymer matrix. In some embodiments, the nanoparticles have a core-shell configuration as illustrated in FIG. 4. In this case, the core 10 of the core-shell can comprise semiconductor materials, such as III-V, II-IV semiconductors, and the like. The shell 20 may be comprised of another semiconductor material or a solvent, for example TOPO, as shown in FIG. 6. In some embodiments, nanoparticles are functionalized, such as with an organic group to facilitate their dispersion in conducting polymer matrix. FIG. 7 shows an exemplary embodiment where nanoparticles 30 (also referred to herein as quantum dots “QD”) are comprised Group IV, II-IV, III-V, II-VI, IV-VI materials. Alternatively, the nanoparticles are comprised of any one or more of CdSe, PbSe, ZnSe, CdS, PbS, Si, SiGe or Ge. In some example the nanoparticles are functionalized with functional groups 40 such as carboxylic (—COOH), amine (—NH2), Phosfonate (—PO4), Sulfonate (—HSO3), Aminoethanethiol, and the like.

Nanoparticle layers can be deposited by known solution processing methods such as spin coating, dip coating, ink-jet printing, and the like. Nanoparticles can also be deposited by vacuum deposition techniques, where applicable. Thickness, particle sizes, luminescent materials type, type of polymer materials (if used) and the nanoparticle loading level in the polymer composite (if polymer composite is used) can be adjusted to maximize absorption in the IR region for IR absorbing nanoparticles and in the UV region for the UV absorbing nanoparticles.

In other embodiments, the nanostructured material is comprised of a mixture of photosensitive nanoparticles and conductive nanoparticles. One or both of the photosensitive and conductive nanoparticles may be functionalized. Examples of conductive nanoparticles include, but are not limited to, any one or more of: single wall carbon nanotubes (SWCNT), TiO₂ nanotubes, or ZnO nanowires. Examples of photosensitive nanoparticles include, but are not limited to, any one or more of: CdSe, ZnSe, PbSe, InP, Si, Ge, SiGe, or Group III-V materials.

In another aspect, the present invention relates to the development of photovoltaic device architectures that promote efficient nanoparticle based photovoltaic devices. In some embodiments, photosensitive nanoparticles. (quantum dots, rods, bipods, tripods, multipods, wires, and the like) are dispersed in a precursor of a high mobility conducting polymer to form a radiation or light harvesting thin film layer which is sandwiched between two conducting electrodes, at least one of these electrodes is transparent. The precursors are preferably of low molecular weight so they can conformally coat the nanoparticles when a thin film of precursor/nanoparticle is formed after removal of the solvent. Nanoparticles can also be functionalized in such a way to facilitate conformal coating of nanoparticles with precursor. The precursor is then polymerized either by thermal means or by using UV radiation to obtain a thin film in which photosensitive nanoparticles are fully encapsulated in the high mobility conducting polymer and facilitate rapid charge transfer of holes and electrons generated when the nanoparticles are exposed to light.

Photosensitive nanoparticles can be made from other photosensitive materials which generate electron hole pairs when exposed to light. Nanoparticles can be made from Cadmium Selenide (CdSe), Zinc Selenide (ZnSe), Lead Selenide (PbSe), Indium Phosphide (InP), Lead Sulfide (PbS), Silicon (Si), Germanium (Ge), Silicon-Germanium (SiGe), III-V materials, and the like.

Nanoparticles can be functionalized with organic or inorganic functional groups. In such embodiments functional groups attached to the surface of nanoparticles include but are not limited to and one or more of: —COOH (carboxylic), —PO4 (phosfonate), —SO3H (sulfonate) and —NH2 (amine).

Examples of high mobility conducting polymers include but are not limited to: Pentacene, P3HT, PEDOT, and the like. Precursors for these polymers may contain one or more thermally polymerizable functional groups. Epoxy is an example a suitable thermally polymerizable functional group. Alternately the precursors may contain one or more UV polymerizable functional group. Acrylic functional group is an example of a suitable UV polymerizable functional group.

In some embodiments, a second conducting polymer material is combined with the precursor of high mobility polymer and photosensitive nanoparticles to aid in the initial film formation before the precursor is polymerized. PVK is an example of a suitable secondary polymeric material. It is preferred that the precursor and secondary polymer be mixed at a maximum ratio of precursor to secondary polymer, as long as the phase separation does not occur after polymerization. In one embodiment pentacene is precursor that is expected to plasticize the PVK film allowing uniform dispersion of photosensitive nanoparticles in the film and also allowing conformal coating of nanoparticles with the precursor.

In some embodiments, the layer of nanostructured material is comprised of a mixture of photosensitive and conductive nanoparticles. Conductive nanoparticles such as carbon nanotubes, TiO2 nanotubes, ZnO nanowires can be mixed with the precursor and photosensitive nanoparticles (optionally with the second conducting polymer) to further enhance charge separation of electrons and holes generated by the nanoparticles upon their exposure to light.

In other embodiments, photosensitive nanoparticles are discreet particles, or alternatively they are attached to conducting nanostructures such as carbon nanotubes (SWCNT), TiO2 nanotubes or ZnO nanowires.

Photosensitive nanoparticles can be chemically attached to the conducting nanostructures based on carbon nanotubes via molecular self assembly so as to form mono layers of these nano particles on the carbon nanotubes. Conducting carbon nanotubes are prepared by methods known in the art. In some embodiments, carbon nanotubes are preferably comprised of single wall carbon nanotubes (SWCNT). The carbon nanotubes can be functionalized to facilitate their dispersion in suitable solvents. Functionalized nanoparticles are reacted with a suitable functional groups (ex: carboxylic or others) on carbon nanotubes to deposit a monolayer of dense continuous nanoparticles by molecular self assembly process. By adjusting the functional group on the nanoparticles and the carbon nanotubes, the distance between the surface of the nanostructure and nanoparticle can be adjusted to minimize the effect of surface states in facilitating charge recombination. This distance is maintained such that electrons tunnel through this gap from the nanoparticles to the highly conducting nanostructures. In some embodiments this distance is a few angstroms, preferably less than 5 angstroms. This facile electron transport will eliminate charge recombination and result in efficient charge separation which will lead to efficient solar energy conversion. In one embodiment, photosensitive nanoparticles are attached to the carbon nanotubes by reacting them in a suitable solvent. Conducting carbon nanotubes may be grown directly on a substrate (ex: metal foil, glass coated with conducting oxide such as ITO) by following methods known in the art. Photosensitive nanoparticles can be attached to the carbon nanotubes grown on the substrate.

In another aspect of the present invention photovoltaic device architectures are taught wherein photosensitive nanoparticles of different sizes are dispersed in a precursor of high mobility polymer to form a single layer sandwiched in between two electrodes with at least one of these electrodes is transparent. A second polymer and/or conducting nanostructures are optionally mixed in the layer containing the nanoparticles and the precursor.

Further, embodiments of the present invention provide photovoltaic device architectures with multi-layer structure in which each layer comprises photosensitive nanoparticles of one or more sizes are dispersed in a precursor of high mobility polymer to form a single layer sandwiched in between two electrodes with at least one of these electrodes is transparent. A second polymer and/or conducting nanostructures are optionally mixed in each of these layers containing the nanoparticles and the precursor.

The present invention further provides photovoltaic devices in which carbon nanotubes attached with photosensitive nanoparticles of different materials of different sizes dispersed in the precursor of high mobility polymer (optionally combined with a second polymer) form a single layer sandwiched in between two electrodes. At least one of these electrodes is transparent. Embodiments of the present invention comprise photovoltaic devices in which carbon nanotubes attached with photosensitive nanoparticles of single size are stacked together to form multiple layers sandwiched in between two electrodes, with at least one of these electrodes is transparent. Additionally, the present invention provides photovoltaic devices where carbon nanotubes attached with photosensitive nanoparticles of single material of single size are stacked together to form multiple layers sandwiched in between two electrodes, with at least one of these electrodes is transparent. In another embodiment, photovoltaic devices are provided comprising carbon nanotubes attached with photosensitive nanoparticles of single material of multiple sizes are stacked together to form multiple layers sandwiched in between two electrodes, where at least one of these electrodes is transparent.

In another aspect, embodiments of the present invention provide photovoltaic devices comprising hole transporting interface layers disposed in between electrode and nanocomposite layers. Embodiments include photovoltaic devices in which electron transporting interface layers are used in between electrode and nanocomposite layer.

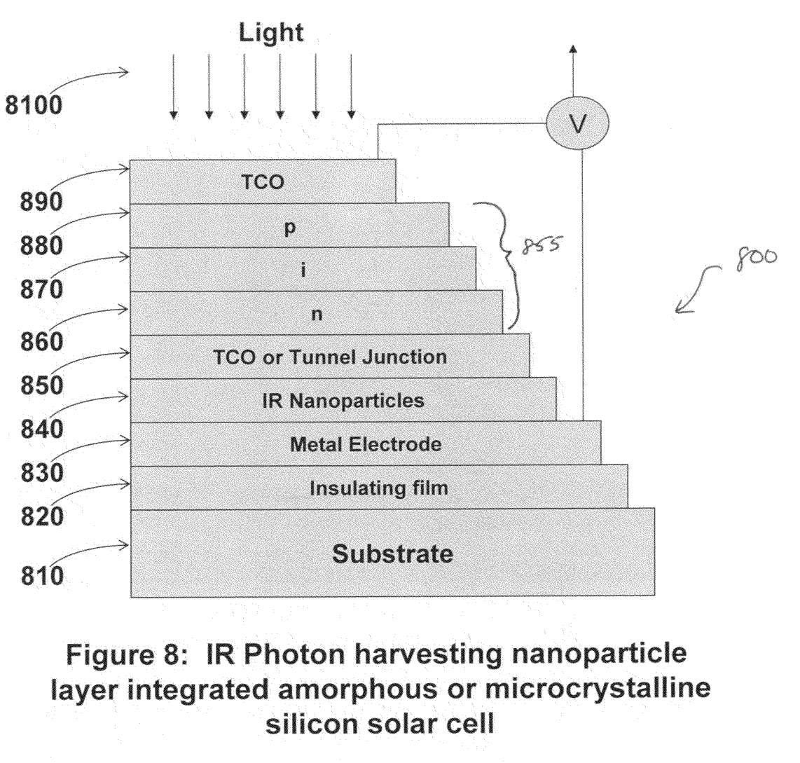

Examples of illustrative embodiments are now described with reference to the Figures. Referring to FIG. 8, one embodiment of a photovoltaic device 800 of the present invention is shown. In this embodiment photovoltaic device is built on a glass, metallic or plastic substrate 810 by depositing an insulating layer 820 and metal layer 830 by methods well known in the art. Layer 840 of nanostructured material with an absorption in the IR region 800-2,000 nm (with a bandgap of 1.2 ev and less) is deposited on the metal layer 830 followed by a recombination layer which comprises a transparent conducting layer (for example ITO) or a tunnel-junction layer 850. These layers are followed by formation of a first photoactive layer 855 disposed above the nanostructured layer 840. In this embodiment, first photoactive layer 855 is comprised of standard amorphous silicon layers that include of n-type amorphous silicon 860, i-type amorphous silicon 870 and p-type amorphous silicon 880. Alternatively, first photoactive layer 855 may be comprised of microcrystalline silicon layers which also include n-type microcrystalline silicon, i-type microcrystalline silicon and p-type microcrystalline silicon. First photoactive layer 855 may be formed by methods well known in the art. A transparent conducting layer (TCO) 890 such as ITO is then deposited on top of the silicon layer. Photovoltaic device is oriented such that sunlight 8100 falls on the TCO 890. The thickness of the amorphous or microcrystalline silicon layers 855 can be adjusted to maximize absorption in the visible region of the solar spectrum. Photovoltaic device described in this embodiment will harvest visible and IR photons from the solar spectrum resulting in higher conversion efficiency compared to the photovoltaic device design without integrating IR absorbing nanoparticles.

Of particular advantage, a recombination layer or tunnel junction layer 850 is disposed between the first photoactive layer and the nanostructured layer. In some embodiments, the recombination layer may be comprised of a doped layer comprised of a material that conducts charge opposite that of the nanostructured material. Thus in some embodiments, the recombination layer will include a doped layer with a charge opposite that of a conducting polymer in the nanostructured material. Alternatively, the recombination layer is a doped layer comprised of a material that conducts charge opposite that of the nanoparticles in the nanostructured material. The recombination layer may further comprise a metal layer and/or an insulator layer coupled to doped layer.

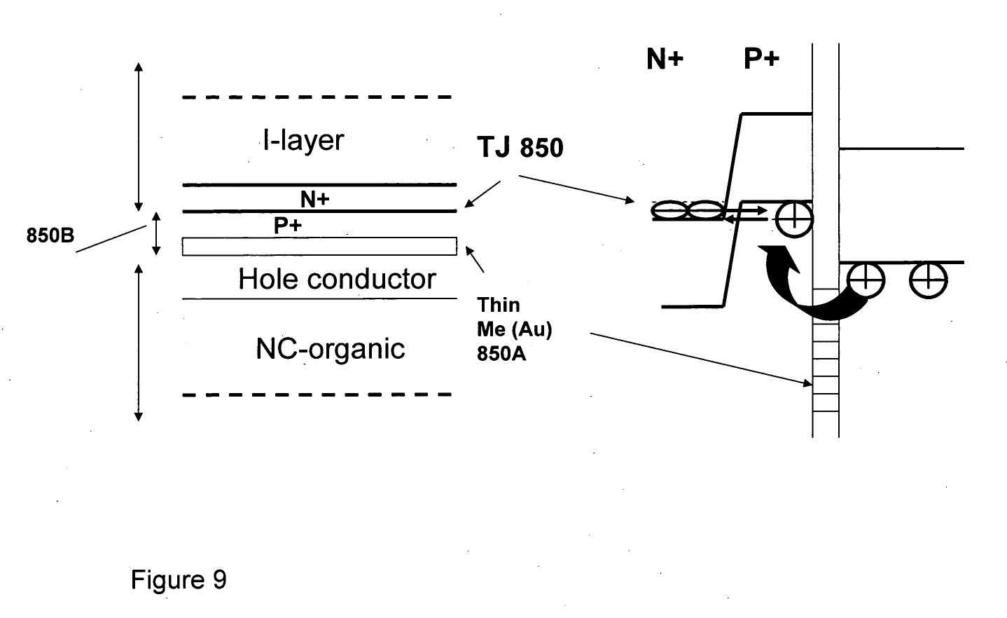

FIG. 9 illustrates recombination layer 850 in more detail. The recombination layer 850 is also sometimes referred to in the Examples below as tunnel junction layer. Nanostructured layer 840 is comprised of a hole conducting material, which may be hole conducting nanoparticles, or nanoparticles dispersed in a hold conducting material, such as a hole conducting polymer. Recombination layer 850 comprises a layer of metal/and or insulator and a layer of p doped material. In general, the recombination layer is a doped layer comprised of a material that conducts charge opposite that of the nanostructured layer conducting polymer. Thus, the recombination layer is a doped layer 850B comprised of a material that conducts charge opposite that of the nanoparticle, or of the conducting polymer depending on the material of the nanostructured layer 840. In some embodiments, the recombination layer further comprises a metal layer 850A coupled to doped layer 850B. Alternatively the recombination layer further comprises an insulating layer (not shown) coupled to doped layer 850B.

To provide a proper top and bottom cell connection for the photovoltaic device of the present invention an interface or recombination layer 850 is provided as generally illustrated in FIG. 9. In one embodiment, the recombination layer may have an additional layer of heavily doped amorphous silicon with the type of doping opposite to the nanostructured layers of the device and/or thin metal or insulating layer between the first photoactive layer and the nanostructured layer, which may be thought of as top and bottom solar cells. The recombination layer is configures to promote charge transport between the layers. Specifically, the recombination layer is configures such that the energy band configuration is favorable for a significant enhancement of the recombination rate between the holes from the bottom nanostructured layers 840 (also referred to as the bottom cell) and electrons from the first photoactive layers 855 (also referred to as the top cell). At the same time the SS participation in the e-h recombination process is suppressed by physical separation between the top and bottom cells.

Referring again to FIG. 9, the top cell has an extra heavily doped P+ layer 850B deposited on the heavily doped N+ contact layer of the first photoactive layer 855, which in this embodiment is the N+ region of a P-I-N semiconductor. The above P+ and N+ layers form a tunnel junction at their interface with extra P+ layer 850B actually becoming a part of the hole conducting component of the bottom nanostructured layer 840. The first and nanostructured layers 855 and 840, respectively are physically separated by a thin tunnel film 850A of metal. In some embodiment, the metal film 850A is comprised of gold (Au) and preferably has a thickness in a range of approximately 5-15 A. Other metal films can be used in other embodiments provided they are thin enough to ensure direct hole tunneling from the nanostructured layers while not causing any significant optical or electrical losses at the interface. Alternatively, an insulting material may be used instead of a metal material. It should be noted that the present invention can be effectively used in photovoltaic device embodiments of opposite types of conductivity in which case extra N+ layer will replace the P+ layer of this embodiment and the nanostructured layer is designed in such that the upper contact layer is electron conducting and not hole conducting.

A corresponding band diagram is also shown in FIG. 9. It can be seen that with the recombination interface of the present invention, favorable energy conditions are created for the holes coming from the nanostructured or bottom cell to be transferred to the extra P+ layer of the top cell through the thin metal film, followed by direct tunneling and recombination with the electrons in the N+ layer of the top cell thus providing an efficient low resistive and minimal loss connection in series for the top and bottom cells. Hence the present invention represents an efficient solution for the problem of proper connection of top and bottom cell.

Further Examples of Photovoltaic Devices with IR Absorbing Layers

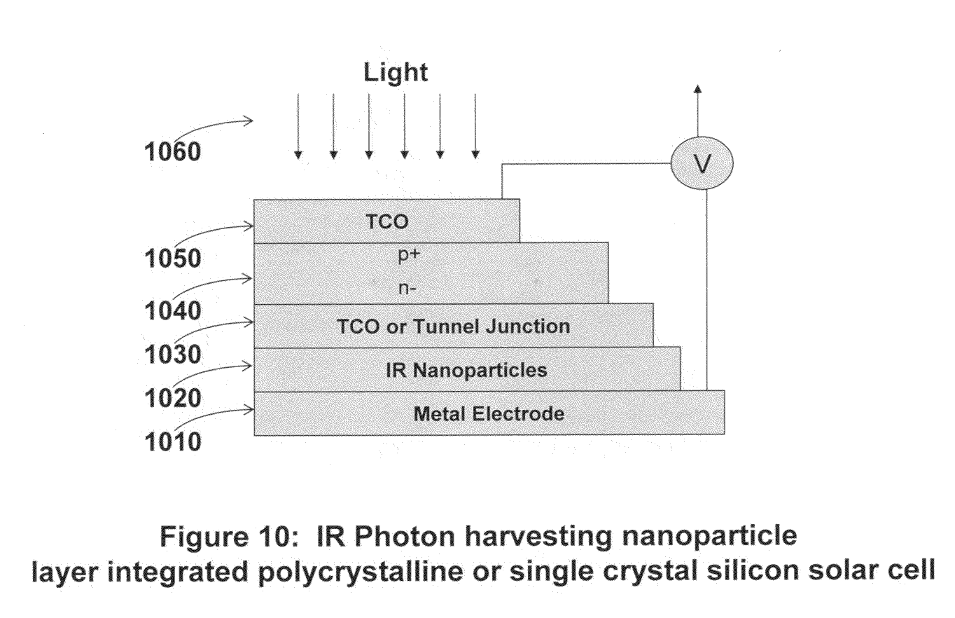

Another embodiment of a photovoltaic device of the present invention is illustrated in FIG. 10. Generally, in this embodiment, the layer of nanostructured material is comprised of IR harvesting nanoparticle layers integrated with polycrystalline or single crystalline silicon layer. The polycrystalline or signal crystal silicon layer forms the first photovoltaic layer of a material that absorbs radiation substantially in the visible range of the solar spectrum. In this embodiment the polycrystalline silicon photovoltaic device is built by methods well known in the art by starting with an n-type polycrystalline wafer 1040 and doping it with a p-type dopant (alternately p-type single crystal wafer can be doped with n-type dopant) on one side of the wafer followed by a transparent conductor or a conducting grid 1050. A transparent conducting layer (ex: ITO) or a tunnel-junction layer 1030 is deposited on the polycrystalline silicon wafer on the opposite side of the first TCO layer 1050. Nanoparticle layer 1020 with an absorption in the IR region 800-2,000 nm (with a bandgap of 1.2 ev and less) is deposited on the TCO or tunnel junction layer 1030 followed by a metal layer 1010. The thickness of polycrystalline silicon layers and the dopant concentrations can be adjusted to maximize absorption in the visible region of the solar spectrum. Photovoltaic device described in this embodiment will harvest visible and IR photons from the solar spectrum resulting in higher conversion efficiency compared to the photovoltaic device design without integrating IR absorbing nanostructures.

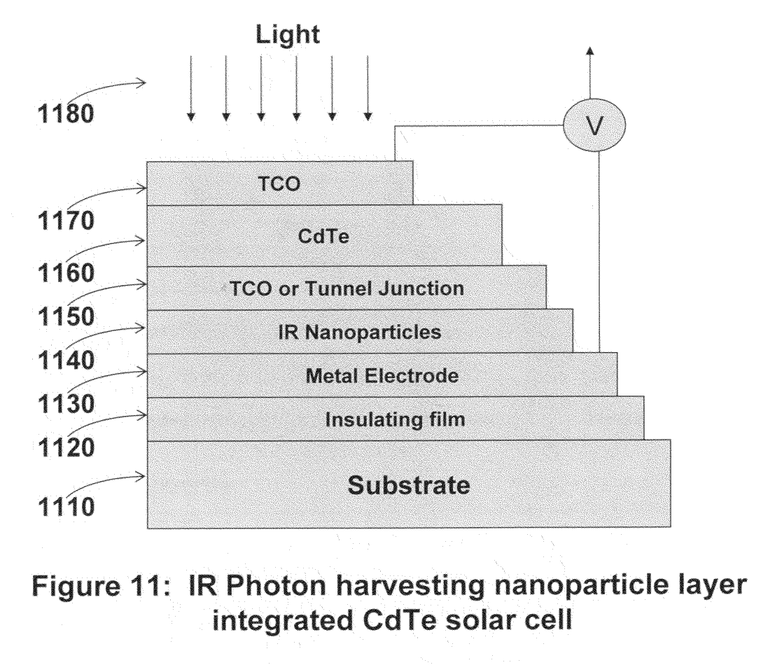

In yet another embodiment, photovoltaic device is provided where the first photoactive layer is comprised of CdTe material as illustrated in FIG. 11. Here the layer of nanostructured material comprises IR harvesting nanoparticle layers. In this embodiment photovoltaic device is built on a glass, metallic or plastic substrate 1110 by depositing an insulating layer 1120 and metal layer 1130 by methods well known in the art. Nanoparticle layer 1140 with an absorption in the IR region 800-2,000 nm (with a bandgap 1.2 ev and less) is deposited on the metal layer 1130 followed by a transparent conducting layer (ex: ITO) or a tunnel-junction layer 1150, which comprises the recombination layer. These layers are followed by a CdTe layer 1160 which is formed by methods well known in the art. A transparent conducting layer TCO 1170 such as ITO is then deposited on top of the silicon layer. Photovoltaic device is oriented such that sunlight 1180 falls on the TCO 1170. The thickness of CdTe layer can be adjusted to maximize absorption in the visible region of the solar spectrum. Photovoltaic device described in this embodiment will harvest visible and IR photons from the solar spectrum resulting in higher conversion efficiency compared to the photovoltaic device design without integrating IR absorbing nanoparticles.

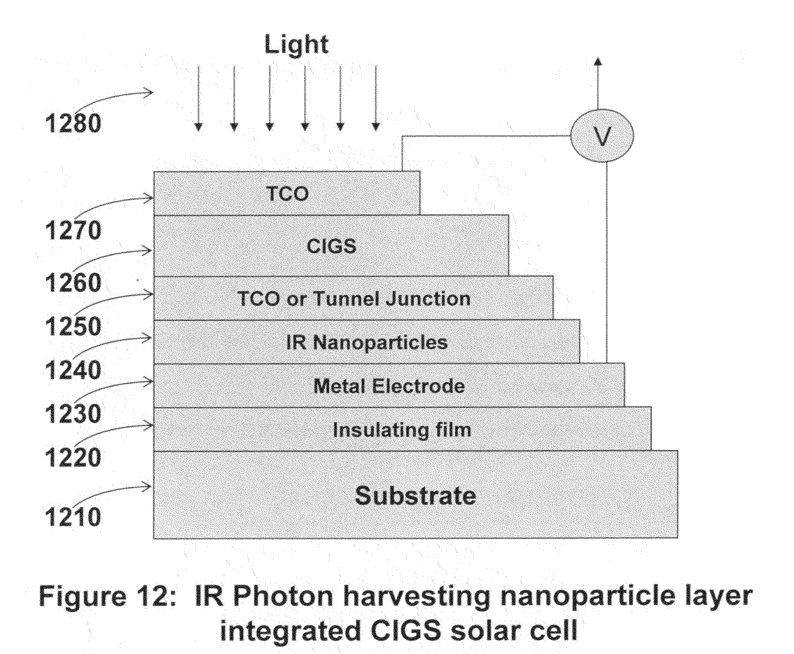

In a further embodiment as shown in FIG. 12, IR harvesting nanoparticle layers are integrated with CIGS layers. In this embodiment photovoltaic device is built on a glass, metallic or plastic substrate 1210 by depositing an insulating layer 1220 and metal layer 1230 by methods well known in the art. The nanoparticle layer 1240 with an absorption in the IR region 800-2,000 nm (with a bandgap of 1.2 ev and less) is deposited on the metal layer 1230 followed by a transparent conducting layer (ex: ITO) or a tunnel-junction layer 1250, which comprises the recombination layer. These layers are followed by CIGS layers 1260 which are formed by methods well known in the art. A transparent conducting layer TCO 1270 such as ITO is then deposited on top of the silicon layer. Photovoltaic device is oriented such that sunlight 1280 falls on the TCO 1270. Thickness of CdTe layer can be adjusted to maximize absorption in the visible region of the solar spectrum. Photovoltaic device described in this embodiment will harvest visible and IR photons from the solar spectrum resulting in higher conversion efficiency compared to the photovoltaic device design without integrating IR absorbing nanoparticles.

Examples of Photovoltaic Device with UV Absorbing Layers

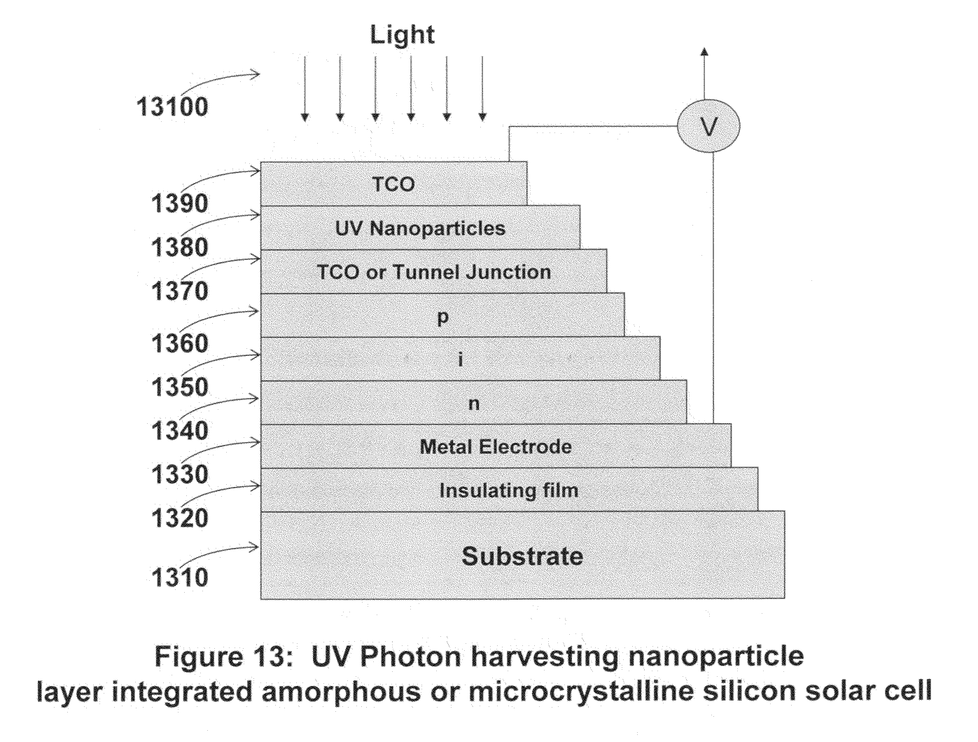

In another aspect of the present invention, a photovoltaic device is provided wherein a first photoactive layer is comprised of a semiconductor material exhibiting absorption of radiation substantially in a visible region of the solar spectrum and a top photoactive layer is comprised of one or more nanoparticles exhibiting absorption of radiation substantially in an UV region of the solar spectrum. A recombination layer is disposed between the first and top layers, and configured to promote charge transport between the first and top layers. Referring to FIG. 13 is shown a top photoactive layer of UV harvesting nanoparticle layers are integrated with a first photoactive layer comprised of amorphous or microcrystalline silicon layers. In this embodiment photovoltaic device is built on a glass, metallic or plastic substrate 1310 by depositing an insulating layer 1320 and metal layer 1330 by methods well known in the art. These layers are followed by standard amorphous or microcrystalline silicon layers which form the first photoactive layer in this embodiment and comprise n-type amorphous silicon 1340, i-type amorphous silicon 1350 and p-type amorphous silicon 1360 by methods well known in the art. A transparent conducting layer TCO or tunnel-junction layer 1370 ( in this case the recombination layer) is then deposited on top of the silicon layer as the recombination layer. Nanoparticle layer 1380 with an absorption in the UV region (with a bandgap of 2 ev higher) is deposited on the TCO or tunnel-junction layer 1370 followed by a transparent conducting layer such as ITO 1390. Photovoltaic device is oriented such that sunlight (100) falls on the TCO (90). Thickness of amorphous silicon layers can be adjusted to maximize absorption in the visible region of the solar spectrum. Photovoltaic device described in this embodiment will harvest visible and UV photons from the solar spectrum resulting in higher conversion efficiency compared to the photovoltaic device design without integrating UV absorbing nanoparticles.

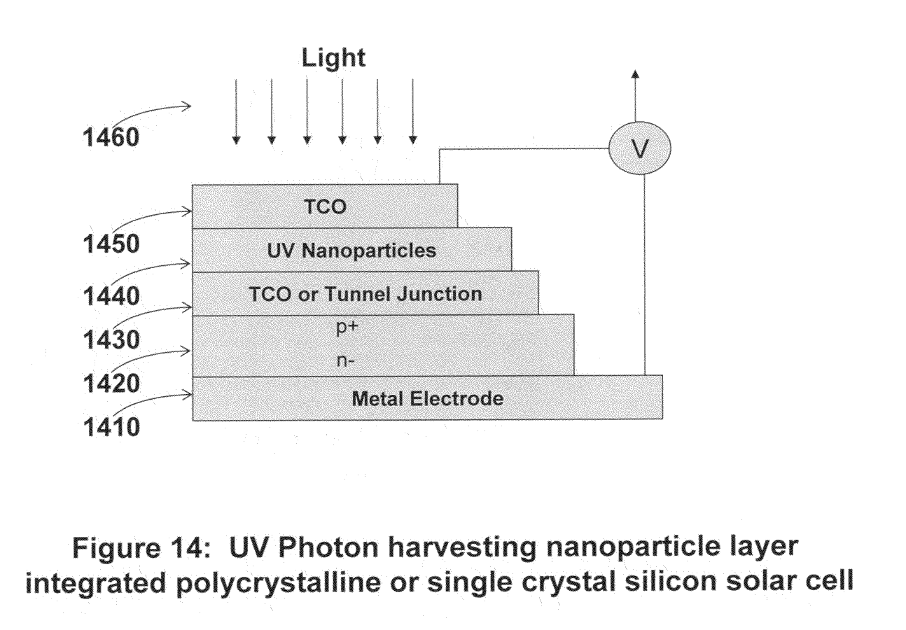

In another embodiment as shown in FIG. 14, UV harvesting nanoparticle layers are integrated with polycrystalline or single crystal silicon layers. In this embodiment polycrystalline or single crystal silicon photovoltaic device is built by methods well known in the art by starting with an n-type polycrystalline wafer 1420 and doping it with a p-type dopant (alternately p-type single crystal wafer can be doped with n-type dopant) on one side of the wafer followed by a metal layer 1410. A transparent conducting layer (ex: ITO) or a tunnel-junction layer 1430 (also referred to as recombination layer) is deposited on the polycrystalline silicon wafer on the opposite side of the metal layer 1410. Nanoparticle layer 1440 with an absorption in the UV region (with a bandgap of 2 ev and higher) is deposited on the TCO or tunnel junction layer 1430 followed by a TCO layer 1450. Thickness of polycrystalline silicon layers and the dopant concentrations can be adjusted to maximize absorption in the visible region of the solar spectrum. Photovoltaic device described in this embodiment will harvest visible and UV photons from the solar spectrum resulting in higher conversion efficiency compared to the photovoltaic device design without integrating UV absorbing nanostructures.

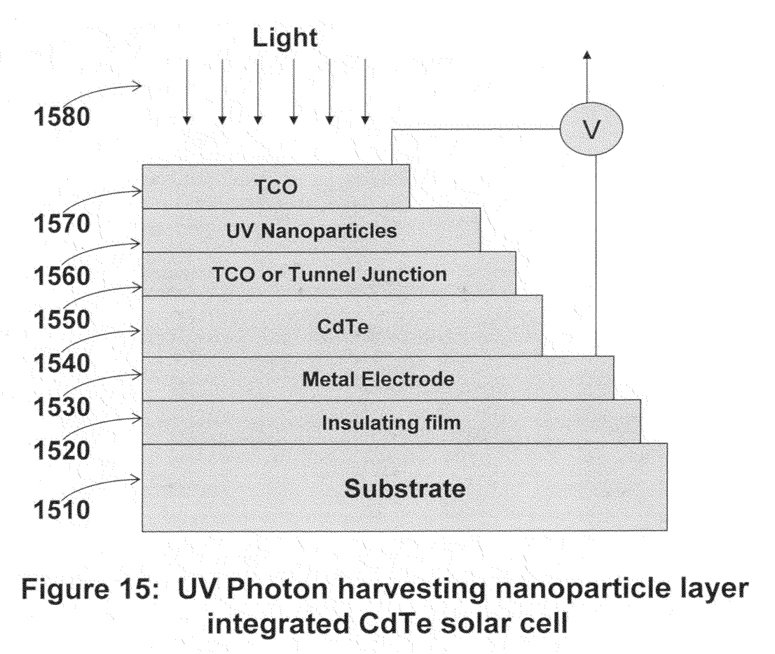

In another embodiment as shown in FIG. 15, UV harvesting nanoparticle layers are integrated with CdTe layers. In this embodiment photovoltaic device is built on a glass, metallic or plastic substrate 1510 by depositing an insulating layer 1520 and metal layer 1530 followed by CdTe layer 1540 by methods well known in the art. A transparent conducting layer (ex: ITO) or a tunnel-junction layer 1550 (in this case the recombination layer) is deposited on the CdTe layer 1540 followed by nanoparticle layer 1560 with an absorption in the UV region (with a bandgap of 2 ev and higher) followed by a transparent conducting layer TCO 1570 such as ITO is then deposited on top of the nanoparticle layer. Photovoltaic device is oriented such that sunlight 1580 falls on the TCO 1570. Thickness of CdTe layer can be adjusted to maximize absorption in the visible region of the solar spectrum. Photovoltaic device described in this embodiment will harvest visible and UV photons from the solar spectrum resulting in higher conversion efficiency compared to the photovoltaic device design without integrating UV absorbing nanoparticles.

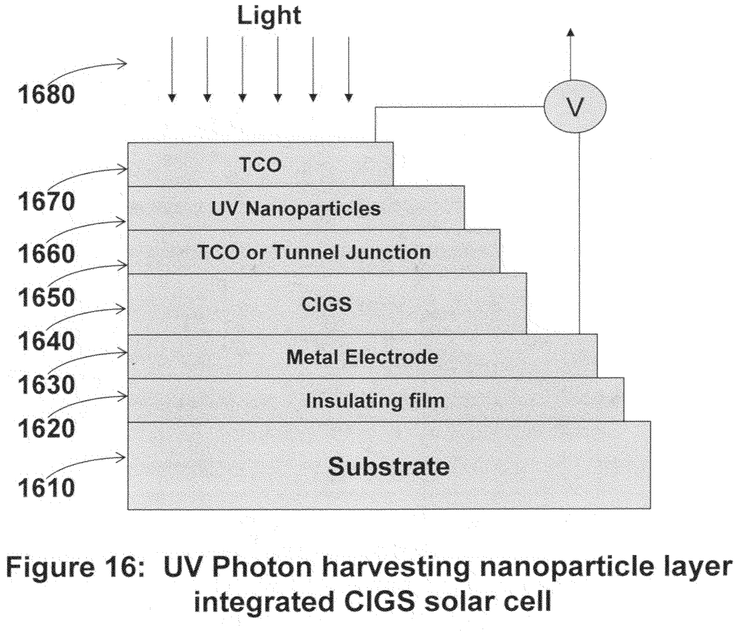

In yet another embodiment as shown in FIG. 16, UV harvesting nanoparticle layers are integrated with CIGS layers. In this embodiment photovoltaic device is built on a glass, metallic or plastic substrate 1610 by depositing an insulating layer 1620 and metal layer 1630 followed by CIGS layers 1640 by methods well known in the art. A transparent conducting layer (ex: ITO) or a tunnel-junction layer 1650 ( also referred to as recombination layer) is deposited on the CIGS layer 1640 followed by nanoparticle layer 1660 with an absorption in the UV region (with a bandgap of 2 ev and higher) followed by a transparent conducting layer TCO 1670 such as ITO is then deposited on top of the nanoparticle layer. Photovoltaic device is oriented such that sunlight 1680 falls on the TCO 1670. Thickness of CIGS layer can be adjusted to maximize absorption in the visible region of the solar spectrum. Photovoltaic device described in this embodiment will harvest visible and UV photons from the solar spectrum resulting in higher conversion efficiency compared to the photovoltaic device design without integrating UV absorbing nanoparticles.

Examples of Photovoltaic Devices with UV and IR Absorbing Layers

In a further aspect, embodiments of the present invention provides a photovoltaic device, comprising: a first photoactive layer comprised of semiconductor material exhibiting absorption of radiation substantially in a visible region of the solar spectrum, and a top photoactive layer comprised of nanostructured material exhibiting absorption of radiation substantially in an UV region of the solar spectrum formed above the first layer. A recombination layer is disposed between the first and top layers, and configured to promote charge transport between the first and top layers. A bottom photoactive layer comprised of nanostructured material exhibiting absorption of radiation substantially in an IR region of the solar spectrum is formed below the first photoactive layer. A second recombination layer is disposed between the first and bottom layers, and configured to promote charge transport between the first and bottom layers.

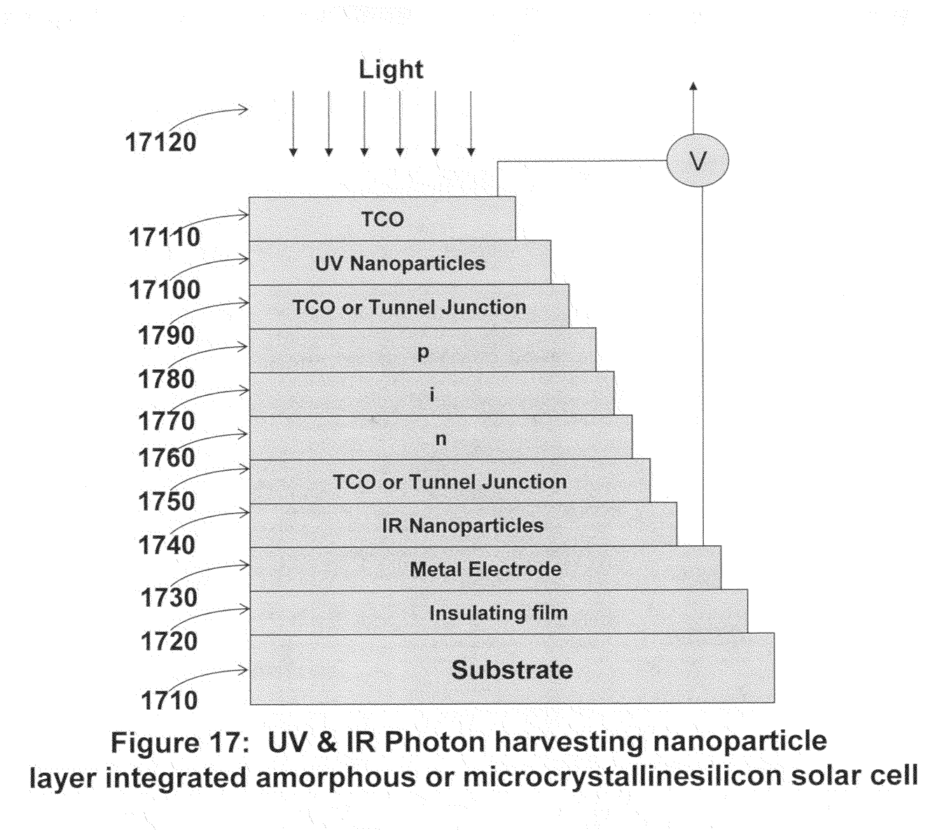

Referring to FIG. 17 is shown a top layer of UV & harvesting nanoparticle layers and a bottom layer of IR harvesting nanoparticles layers with a first photoactive layer disposed there between. In this embodiment, the first photoactive layer comprises amorphous or microcrystalline silicon layers. In this embodiment photovoltaic device is built on a glass, metallic or plastic substrate 1710 by depositing an insulating layer 1720 and metal layer 1730 by methods well known in the art. Nanoparticle layer 1740 with an absorption in the IR region 800-2,000 nm (with a bandgap less than 1.2 ev) is deposited on the metal layer 1730 followed by a transparent conducting layer (ex: ITO) or a tunnel-junction layer (or recombination layer) 1750. These layers are followed by depositing of the first photoactive layer, in this case standard amorphous or microcrystalline silicon layers that comprise n-type amorphous silicon 1760, i-type amorphous silicon 1770 and p-type amorphous silicon 1780, formed by methods well known in the art. A transparent conducting layer TCO 1790 or tunnel-junction layer is then deposited on top of the silicon layer. Nanoparticle layer 17100 with an absorption in the UV region (with a bandgap higher than 2 ev) is deposited on the TCO or tunnel-junction layer (90) followed by a transparent conducting layer such as ITO 17110. Photovoltaic device is oriented such that sunlight 17120 falls on the TCO 1790. Thickness of amorphous silicon layers can be adjusted to maximize absorption in the visible region of the solar spectrum. Photovoltaic device described in this embodiment will harvest visible, UV and IR photons from the solar spectrum resulting in higher conversion efficiency compared to the photovoltaic device design without integrating UV and IR absorbing nanoparticles.

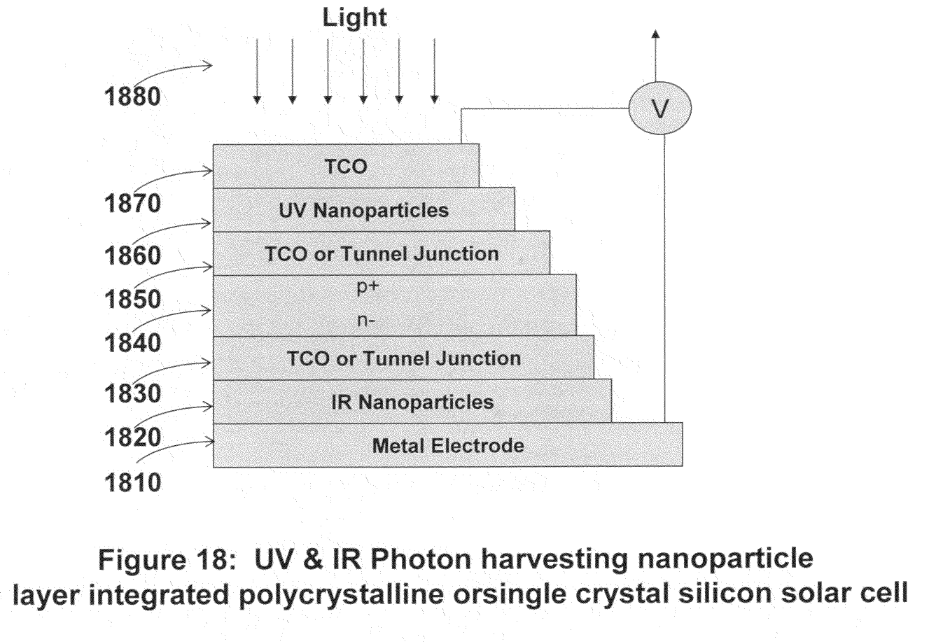

Another embodiment is depicted in FIG. 18 which shows UV & IR harvesting nanoparticle layers are integrated with polycrystalline or single crystal silicon layers. In this embodiment polycrystalline or single crystal silicon photovoltaic device is built by methods well known in the art by starting with an n-type polycrystalline wafer 1840 and doping it with a p-type dopant (alternately p-type single crystal wafer can be doped with n-type dopant) on one side of the wafer followed by an TCO or tunnel-junction layer 1830. A transparent conducting layer (ex: ITO) or a tunnel-junction layer (also referred to as recombination layer) 1860 is deposited on the polycrystalline silicon wafer on the opposite side of the first TCO or tunnel-junction layer 1830. Nanoparticle layer 1860 with an absorption in the UV region (with a bandgap higher than 2 ev) is deposited on the TCO or tunnel junction layer 1830 followed by a TCO layer 1870. Nanoparticle layer 1820 with an absorption in the IR region (with a bandgap less than 1.2 ev) is deposited on the TCO or tunnel junction layer 1830 followed by a metal electrode layer 1810. Thickness of polycrystalline silicon layers and the dopant concentrations can be adjusted to maximize absorption in the visible region of the solar spectrum. Photovoltaic device described in this embodiment will harvest visible, UV and IR photons from the solar spectrum resulting in higher conversion efficiency compared to the photovoltaic device design without integrating UV and IR absorbing nanostructures.

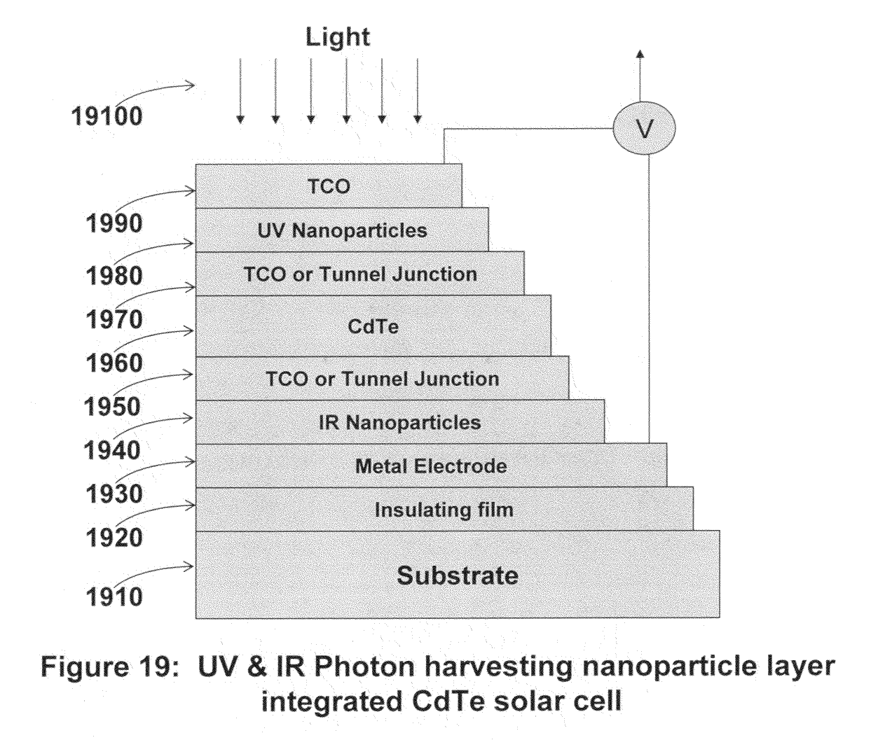

FIG. 19 illustrates another embodiment where 21 UV & IR harvesting nanoparticle layers are integrated with CdTe layers. In this embodiment photovoltaic device is built on a glass, metallic or plastic substrate 1910 by depositing an insulating layer 1920 and metal layer 1930 followed by nanoparticle layer 1940 with an absorption in the IR region (with a bandgap less than 1.2 ev) followed by a transparent conducting layer TCO layer 1950 or tunnel-junction layer. CdTe layer 1960 is then deposited on TCO or tunnel-junction layer (or recombination layer) 1950 by methods well known in the art. A transparent conducting layer (ex: ITO) or a tunnel-junction layer 1970 is deposited on the CdTe layer 1960 followed by nanoparticle layer 1980 with an absorption in the UV region (with a bandgap greater than 2 ev) followed by a transparent conducting layer TCO 1990 such as ITO is then deposited on top of the nanoparticle layer. Photovoltaic device is oriented such that sunlight 19100 falls on the TCO 1990. Thickness of CdTe layer can be adjusted to maximize absorption in the visible region of the solar spectrum. Photovoltaic device described in this embodiment will harvest visible, UV and IR photons from the solar spectrum resulting in higher conversion efficiency compared to the photovoltaic device design without integrating UV and IR absorbing nanoparticles.

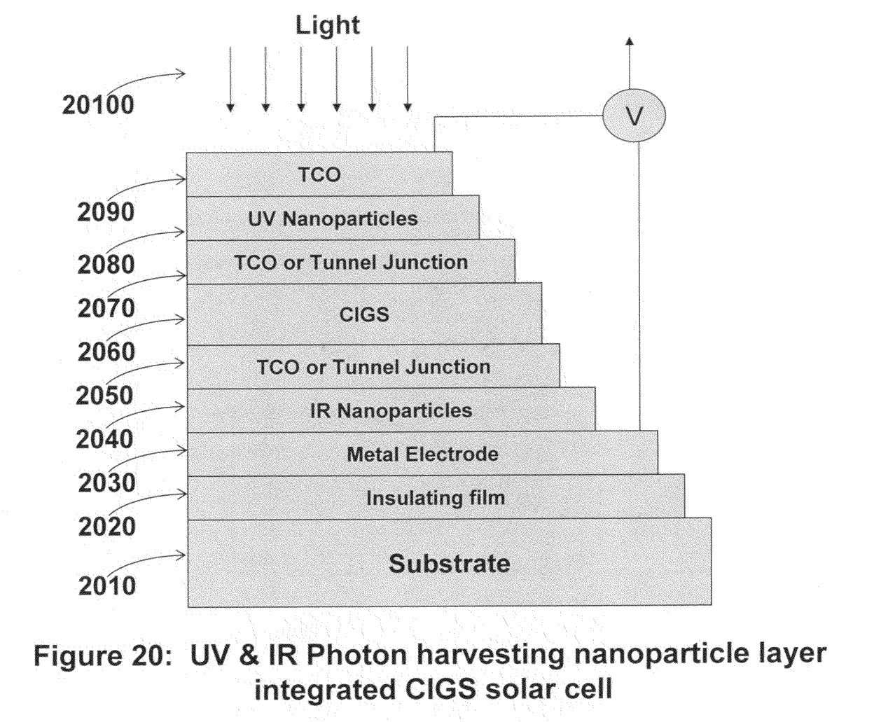

FIG. 20 illustrates yet another embodiment where UV & IR harvesting nanoparticle layers are integrated with CIGS layers. In this embodiment photovoltaic device is built on a glass, metallic or plastic substrate 2010 by depositing an insulating layer 2020 and metal layer 2030 followed by nanoparticle layer 2040 with an absorption in the IR region (with a bandgap less than 1.2 ev) followed by a transparent conducting layer TCO layer or tunnel-junction layer (or recombination layer) 2050. CIGS layers 2060 are then deposited on TCO or tunnel-junction layer 2050 by methods well known in the art. A transparent conducting layer (ex: ITO) or a tunnel-junction layer 2070 is deposited on the CIGS layers 2060 followed by nanoparticle layer 2080 with an absorption in the UV region (with a bandgap greater than 2 ev) followed by a transparent conducting layer TCO 2090 such as ITO is then deposited on top of the nanoparticle layer. Photovoltaic device is oriented such that sunlight 20100 falls on the TCO 2090. Thickness of CIGS layers can be adjusted to maximize absorption in the visible region of the solar spectrum. Photovoltaic device described in this embodiment will harvest visible, UV and IR photons from the solar spectrum resulting in higher conversion efficiency compared to the photovoltaic device design without integrating UV and IR absorbing nanoparticles.

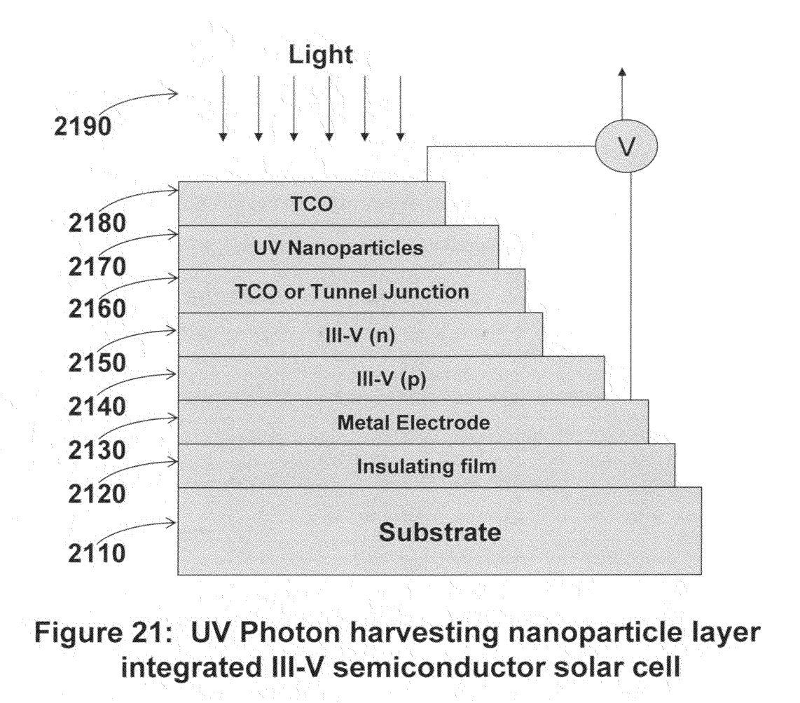

In another aspect of the present invention, compound semiconductor materials may be employed as the first photoactive layer which absorbs radiation substantially in the visible region of the solar spectrum. FIG. 21 illustrates a photovoltaic device with UV harvesting nanoparticle layers (ex: InP quantum dots) integrated with III-V semiconductor layers (ex: GaAs). In this embodiment photovoltaic device is built on a substrate 2110 by depositing an insulating layer 2120 and metal layer 2130 by methods well known in the art. These layers are followed by III-V semiconductor layers that consist of p-type semiconductor 2140 and n-type semiconductor 2150 by methods well known in the art. A transparent conducting layer TCO 2160 or tunnel-junction layer is then deposited on top of the III-V layer. Nanoparticle layer 2170 with an absorption in the UV region (with a bandgap higher than 2 ev) is deposited on the TCO or tunnel-junction layer (also referred to as recombination layer) 2160 followed by a transparent conducting layer 2180. Photovoltaic device is oriented such that sunlight 2190 falls on the TCO 2180. Photovoltaic device described in this embodiment will harvest visible and UV photons from the solar spectrum resulting in higher conversion efficiency compared to the photovoltaic device design without integrating UV absorbing nanoparticles.

### Examples of Four Junction Photovoltaic Devices

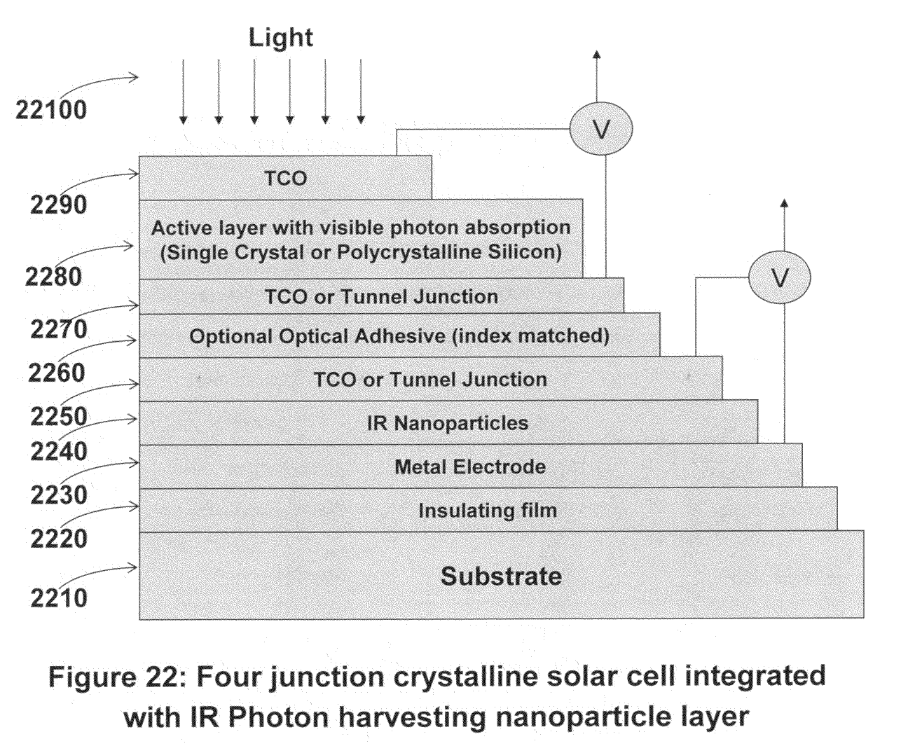

Some embodiments of the present invention provide a four junction photovoltaic device. FIG. 22 illustrates an IR harvesting nanoparticle photovoltaic device and a crystalline (single crystal or polycrystalline) photovoltaic device is integrated to form a four junction photovoltaic device. In this embodiment crystalline silicon photovoltaic device is built by methods well known in the art by starting with an n-type crystalline silicon wafer 2280 and doping it with a p-type dopant (alternately p-type silicon wafer can be doped with n-type dopant) on one side of the wafer followed by a transparent conducting layer 2270. Crystalline silicon photovoltaic device is completed by depositing a transparent conducting layer (ex: ITO) or a tunnel-junction layer (the first recombination layer) 2290 on the silicon wafer on the opposite side of the first TCO layer 2270. Photovoltaic device containing IR absorbing nanoparticles is built by starting with a substrate (glass, metal or plastic) 2210 and depositing a dielectric layer 2220 followed by metal layer 2230 by using standard methods known in the art. A nanoparticle layer 2240 with an absorption in the IR region (with a bandgap less than 1 ev) is deposited on the metal layer 2230 followed by a TCO or tunnel junction layer ( in this case the second recombination layer) 2250. A four junction tandem cell shown in FIG. 22 is built by combining the crystalline silicon photovoltaic device and the IR absorbing nanoparticle photovoltaic device. An optical adhesive layer 2260 can be optionally used to bond the two cells together. Relative performance of the individual cells can be adjusted to maximize absorption in the visible and IR region of the solar spectrum. Photovoltaic device described in this embodiment will harvest visible and IR photons from the solar spectrum resulting in higher conversion efficiency compared to the photovoltaic device design without integrating a photovoltaic device containing IR absorbing nanostructures.

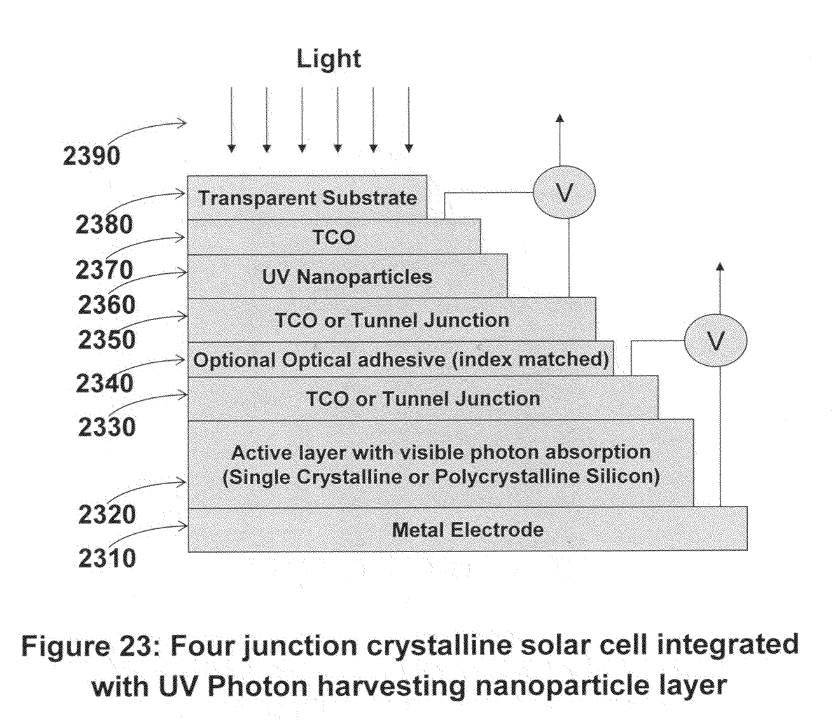

FIG. 23 illustrates another embodiment where UV harvesting nanoparticle photovoltaic device and crystalline (single crystal or polycrystalline) silicon photovoltaic device are integrated to form a four junction photovoltaic device. In this embodiment crystalline silicon photovoltaic device is built by methods well known in the art by starting with an n-type crystalline silicon wafer 2320 and doping it with a p-type dopant (alternately p-type silicon wafer can be doped with n-type dopant) on one side of the wafer followed by a metal layer 2310. Crystalline silicon photovoltaic device is completed by depositing a transparent conducting layer (ex: ITO) or a tunnel-junction layer (in this case the first recombination layer) 2330 on the silicon wafer on the opposite side of the metal layer 2310. Photovoltaic device containing UV absorbing nanoparticles is built by starting with a transparent substrate (glass, or plastic) 2380 and depositing a transparent conducting TCO layer 2370 by using standard methods known in the art. A nanoparticle layer 2360 with an absorption in the IR region (with a bandgap less than 2 ev) is deposited on the TCO layer 2370 followed by a TCO or tunnel junction layer ( in this case the second recombination layer) 2350. A four junction tandem cell shown in FIG. 23 is built by combining the crystalline silicon photovoltaic device and the IR absorbing nanoparticle photovoltaic device. An optical adhesive layer 2340 can be optionally used to bond the two cells together. Relative performance of the individual cells can be adjusted to maximize absorption in the visible and UV region of the solar spectrum. Photovoltaic device described in this embodiment will harvest visible and UV photons from the solar spectrum resulting in higher conversion efficiency compared to the photovoltaic device design without integrating a photovoltaic device containing UV absorbing nanostructures.

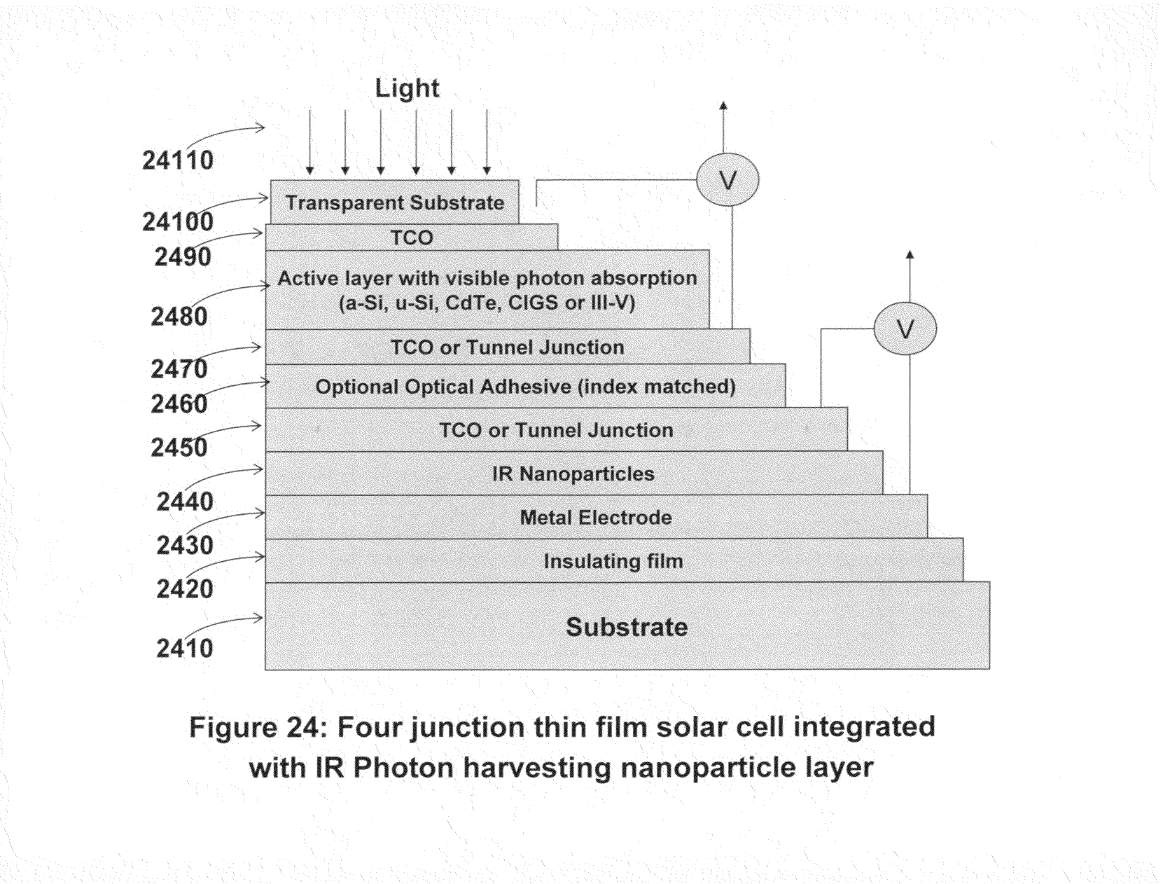

FIG. 24 depicts yet another embodiment where IR harvesting nanoparticle photovoltaic device and a thin film (a-Si, u-Si, CdTe, CIGS, III-V) photovoltaic device is integrated to form a four junction photovoltaic device. In this embodiment thin film photovoltaic device is built by methods well known in the art by starting with a transparent substrate 24100 and depositing transparent conducting layer 2490 followed by active thin film layer 2480 and a transparent conductor or tunnel junction layer (the first recombination layer) 2470. Photovoltaic device containing IR absorbing nanoparticles is built by starting with a substrate (glass, metal or plastic) 2410 and depositing a dielectric layer 2420 followed by metal layer 2430 by using standard methods known in the art. A nanoparticle layer 2440 with an absorption in the IR region (with a bandgap less than 1 ev) is deposited on the metal layer 2430 followed by a TCO or tunnel junction layer ( the second recombination layer) 2450. A four junction tandem cell shown in FIG. 24 is built by combining the crystalline silicon photovoltaic device and the IR absorbing nanoparticle photovoltaic device. An optical adhesive layer 2460 can be optionally used to bond the two cells together. Relative performance of the individual cells can be adjusted to maximize absorption in the visible and IR region of the solar spectrum. Photovoltaic device described in this embodiment will harvest visible and IR photons from the solar spectrum resulting in higher conversion efficiency compared to the photovoltaic device design without integrating a photovoltaic device containing IR absorbing nanostructures.

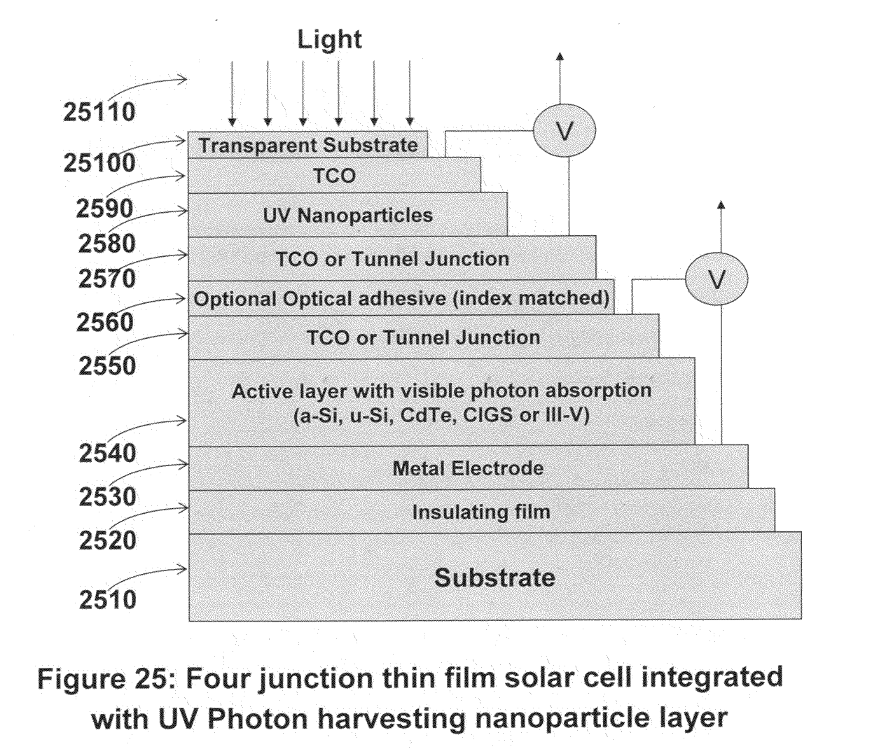

An additional embodiment of a four junction photovoltaic device according to embodiments of the present invention is shown in FIG. 25 where UV harvesting nanoparticle photovoltaic device and a thin film (a-Si, u-Si, CdTe, CIGS, III-V) photovoltaic device is integrated to form a four junction photovoltaic device. In this embodiment thin film photovoltaic device is built by methods well known in the art by starting with a transparent substrate 25100 and depositing transparent conducting layer 2590 followed by active thin film layer 2580 and a transparent conductor or tunnel junction layer (e.g. first recombination layer) 2570. Photovoltaic device containing UV absorbing nanoparticles is built by starting with a substrate (glass, metal or plastic) 2510 and depositing a dielectric layer 2520 followed by metal layer 2530 by using standard methods known in the art. A nanoparticle layer 2540 with an absorption in the UV region (with a bandgap less than 1 ev) is deposited on the metal layer 2530 followed by a TCO or tunnel junction layer (e.g, second recombination layer) 2550. A four junction tandem cell shown in FIG. 25 is built by combining the crystalline silicon photovoltaic device and the UV absorbing nanoparticle photovoltaic device. An optical adhesive layer 2560 can be optionally used to bond the two cells together. Relative performance of the individual cells can be adjusted to maximize absorption in the visible and UV region of the solar spectrum. Photovoltaic device described in this embodiment will harvest visible and UV photons from the solar spectrum resulting in higher conversion efficiency compared to the photovoltaic device design without integrating a photovoltaic device containing UV absorbing nanostructures.

Examples of Photovoltaic Devices with Functionalized Nanoparticles

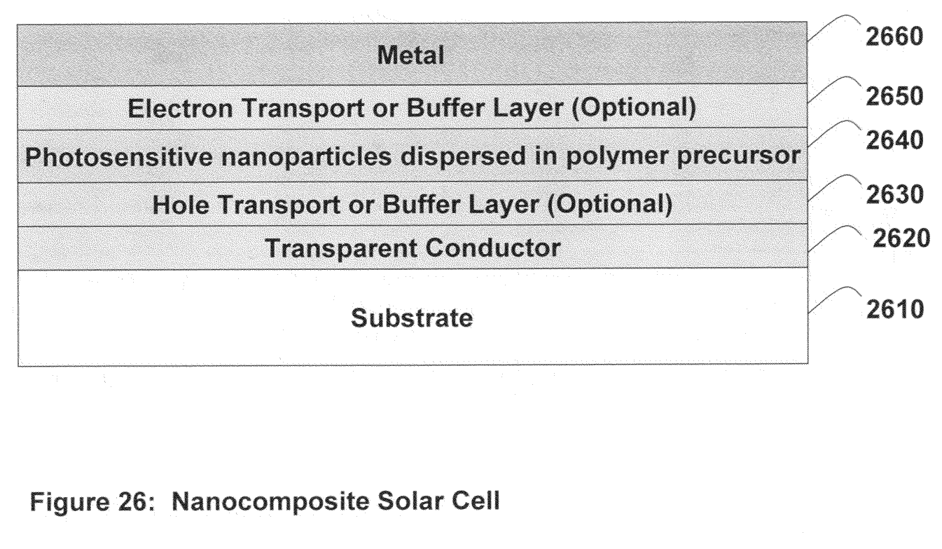

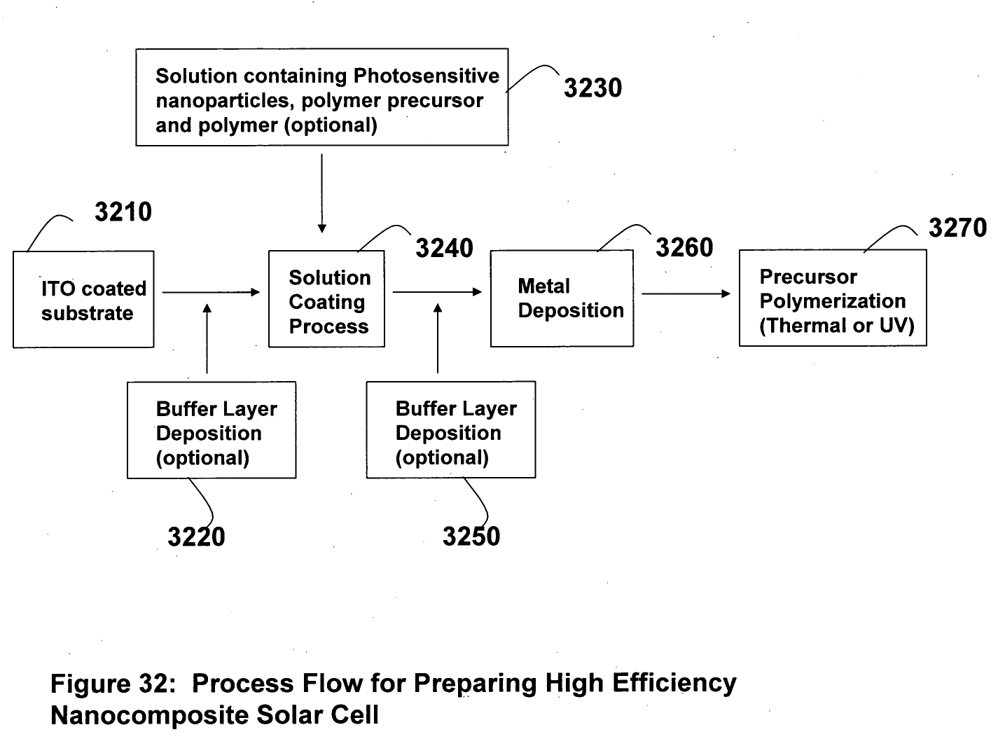

In a further aspect, embodiments of the present invention provides a photovoltaic device, comprising: a first photoactive layer comprised of semiconductor material exhibiting absorption of radiation substantially in a visible region of the solar spectrum, and on or more photoactive layer comprised of nanostructured material exhibiting absorption of radiation substantially in an UV and/or region of the solar spectrum wherein one or more of the nanostructured materials comprise functionalized nanoparticles. FIG. 26 illustrates one embodiment of a nanocomposite photovoltaic device according to the present invention. This photovoltaic device is formed by coating a thin layer of nanocomposite 2640 containing photosensitive nanoparticles and precursor of a high mobility polymer such as pentacene on a glass substrate 2610 coated with a transparent conductor 2620 such as ITO followed by the deposition of cathode metal layer 2660. Photosensitive nanoparticles can be made from Group IV, II-IV, II-VI, IV-VI, III-V materials. Examples of photosensitive nanoparticles include, but are not limited to any one or more of: Si, Ge, CdSe, PbSe, ZnSe, CdTe, CdS, or PbS. Nanoparticle sizes can be varied, for example in a range of approximately 2 nm to 10 nm to obtain a range of bandgaps. These nanoparticles can be prepared by methods known in the art. Nanoparticles can be functionalized by methods known in the art. Examples of suitable functional groups include, but are not limited to: carboxylic (—COOH), amine (—NH2), Phosfonate (—PO4), Sulfonate (—HSO3), Aminoethanethiol, etc. Nanocomposite layer 2640 of photosensitive nanoparticles dispersed in precursor of high mobility polymer such as pentacene can be deposited on ITO coated glass substrate by spin coating or other well known solution processing techniques. This layer can be one monolayer or multiple monolayers. Precursor in the nanocomposite layer 2640 is polymerized by heating the films to appropriate temperatures to initiate polymerization of pentacene precursor. If a UV polymerizable precursor is used the polymerization can be achieved by exposing the film to UV from the ITO side 2620 of FIG. 26. Embodiment of the photovoltaic device may be fabricated according the method illustrated in FIG. 32. In this device electron hole pairs are generated when sunlight is absorbed by the nanoparticles and the resulting electrons are rapidly transported by the high mobility polymer such as pentacene to the cathode for collection. This rapid removal of electrons from the electron-hole pairs generated by the nanoparticles eliminates the probability of electron-hole recombination commonly observed in nanoparticle based photovoltaic device devices.

According to the embodiments shown in FIG. 26, hole injecting/transporting interface layer or a buffer layer 2630 may be disposed between ITO 2620 and nanocomposite layer 2640. Alternatively, electron injecting/transporting interface layer, also referred to recombination layer, 2650 may be disposed between metal layer 2660 and nanocomposite layer 2640.

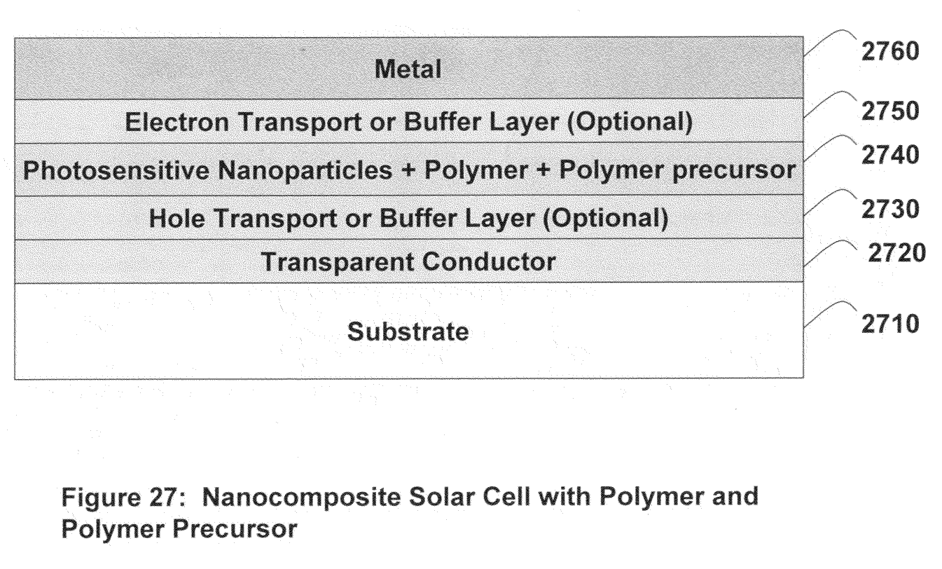

FIG. 27 depicts another embodiment of nanocomposite photovoltaic device. This photovoltaic device is fabricated by coating a nanocomposite layer 2740 comprising photosensitive nanoparticles, a high mobility polymer such as PVK or P3HT and a precursor of a high mobility polymer 2740 such as pentacene on a glass substrate 2710 coated with a transparent conductor 2720 such as ITO followed by the deposition of cathode metal layer 2760. Photosensitive nanoparticles comprise Group IV, II-IV, II-VI, IV-VI, III-V materials. Examples of photosensitive nanoparticles include, but are not limited to any one or more of: Si, Ge, CdSe, PbSe, ZnSe, CdTe, CdS or PbS. Nanoparticle sizes can be varied (for example in a range of approximately 2 nm to 10 nm) to obtain a range of bandgaps. These nanoparticles can be prepared by methods known in the art. Nanoparticles can be functionalized by methods known in the art. Functional groups include, but are not limited to: carboxylic (—COOH), amine (—NH2), Phosfonate (—PO4), Sulfonate (—HSO3), Aminoethanethiol, etc. Nanocomposite layer 2740 of photosensitive nanoparticles dispersed in high mobility polymer such as PVK or P3HT and a precursor of high mobility polymer such as pentacene can be deposited on ITO coated glass substrate by spin coating or other known solution processing techniques. Nanocomposite layer 2740 can be one monolayer or multiple monolayers. In some embodiments, the precursor in the nanocomposite layer 2740 is polymerized by heating the films to appropriate temperatures to initiate polymerization of pentacene precursor. If a UV polymerizable precursor is used the polymerization can be achieved by exposing the film to UV from the ITO side 2720. In some embodiments, the photovoltaic device is fabricated according to the method shown in FIG. 32. Photovoltaic devices built according this embodiment are expected to have high efficiency. In this device electron hole pairs are generated when sunlight is absorbed by the nanoparticles and the resulting electrons are rapidly transported by the high mobility polymer such as pentacene to the cathode for collection. This rapid removal of electrons from the electron-hole pairs generated by the nanoparticles eliminates the probability of electron-hole recombination commonly observed in nanoparticle based photovoltaic device devices.

Additionally, in some embodiments hole injecting/transporting interface layer or a buffer layer 2730 can be used between ITO 2720 and nanocomposite layer 2740. In an alternative embodiment, electron injecting/transporting interface layer 2750 can be used between metal layer 2760 and nanocomposite layer 2740.

Examples of Photovoltaic Devices with Functionalized Nanoparticles and Conducting Nanoparticles/Nanostructures

In some embodiments, the nanostructured material is comprised of a mixture of photosensitive nanoparticles and conductive nanoparticles. One, or both of, the photosensitive and conductive nanoparticles may be functionalized. Examples of conductive nanoparticles are comprised of any one or more of: single wall carbon nanotubes (SWCNT), TiO₂ nanotubes, or ZnO nanowires. Examples of photosensitive nanoparticles are comprised of any one or more of: CdSe, ZnSe, PbSe, InP, Si, Ge, SiGe, or Group III-V materials.

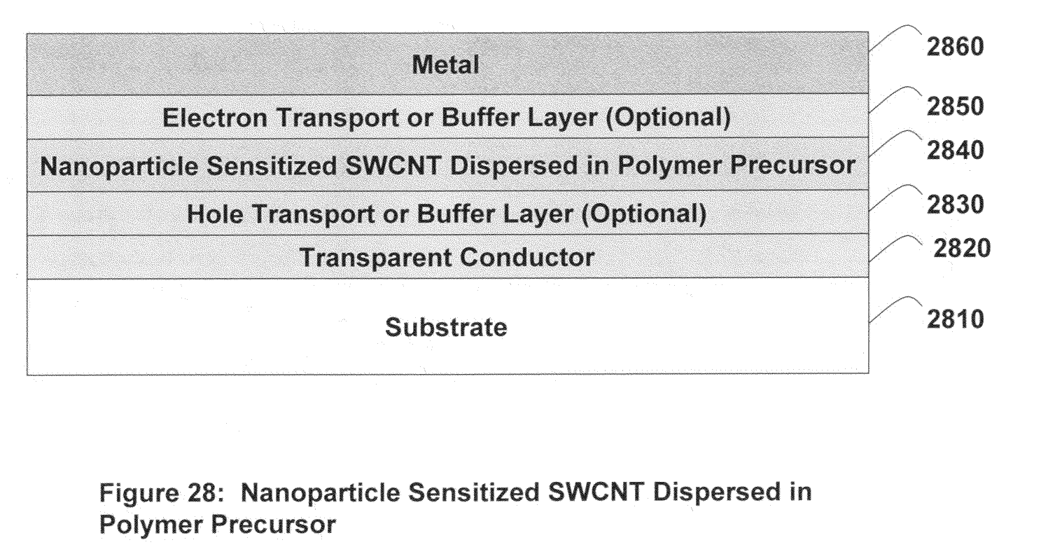

FIG. 28 illustrates an embodiment of nanocomposite photovoltaic device. This photovoltaic device can be built by coating a thin layer of nanocomposite 2840 containing photosensitive nanoparticles attached to a conducting nanostructure dispersed in a precursor of a high mobility polymer such as pentacene on a glass substrate 2810 coated with a transparent conductor 2820 such as ITO followed by the deposition of cathode metal layer 2860. Photosensitive nanoparticles can be made from Group IV, II-IV, II-VI, IV-VI, III-V materials. Examples of photosensitive nanoparticles include Si, Ge, CdSe, PbSe, ZnSe, CdTe, CdS, PbS. Nanoparticle sizes can be varied (for example: 2-10 nm) to obtain a range of bandgaps. These nanoparticles can be prepared by following the methods well known in the art. Nanoparticles can be functionalized by following the methods well known in the art. Functional groups can include carboxylic (—COOH), amine (—NH2), Phosfonate (—PO4), Sulfonate (—HSO3), Aminoethanethiol, etc. Conducting nanostructures can be made from carbon nanotubes (SWCNT), TiO2 nanotubes or ZnO nanowires. Conducting nanostructures can be functionalized to facilitate the attachment of photosensitive nanoparticles to the surface of conducting nanostructures. Nanocomposite layer 2840 of photosensitive nanoparticles are attached to conducting nanostructures and dispersed in precursor of high mobility polymer such as pentacene. This layer 2840 is deposited on ITO coated glass substrate by spin coating or other known solution processing techniques. This layer can be one monolayer or multiple monolayers. A precursor in the nanocomposite layer 2840 is polymerized by heating the films to appropriate temperatures to initiate polymerization of precursor. If a UV polymerizable precursor is used the polymerization can be achieved by exposing the film to UV from the ITO side 2820. Methods shown in FIG. 32 may be carried our to form the photovoltaic device. In this device electron hole pairs are generated when sunlight is absorbed by the nanoparticles and the resulting electrons are rapidly transported by the conducting nanostructures and high mobility polymer such as pentacene to the cathode for collection. This rapid removal of electrons from the electron-hole pairs generated by the nanoparticles eliminates the probability of electron-hole recombination commonly observed in nanoparticle based photovoltaic device devices. Additionally hole injecting/transporting interface layer or a buffer layer 2830 can be employed between ITO 2820 and nanocomposite layer 2840. In another embodiment, electron injecting/transporting interface layer 2850 can be used between metal layer 2860 and nanocomposite layer 2840.

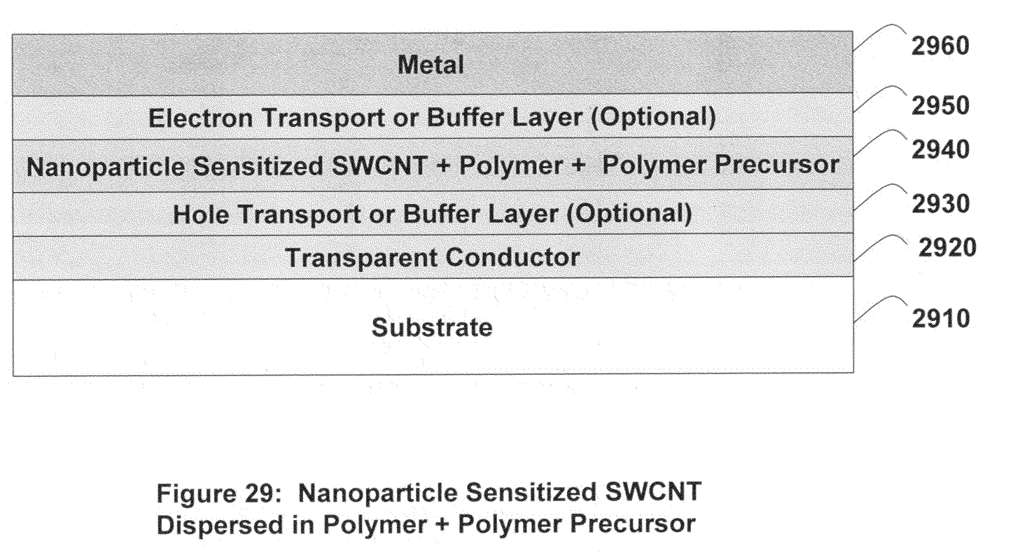

A further embodiment of nanocomposite photovoltaic device is shown in FIG. 29. This photovoltaic device can be built by coating a nanocomposite layer 2940 containing photosensitive nanoparticles attached to a conducting nanostructure dispersed in a high mobility polymer such as PVK or P3HT and a precursor of a high mobility polymer such as pentacene 2940 on a glass substrate 2910 coated with a transparent conductor 2920 such as ITO followed by the deposition of cathode metal layer 2960. Photosensitive nanoparticles may comprise Group IV, II-IV, II-VI, IV-VI, III-V materials. Examples of photosensitive nanoparticles include, but are not limited to any one or more of: Si, Ge, CdSe, PbSe, ZnSe, CdTe, CdS, PbS. Nanoparticle sizes can be varied (for example: 2-10 nm) to obtain a range of bandgaps. These nanoparticles can be prepared methods well known in the art. Nanoparticles can be functionalized by methods well known in the art. Functional groups can include carboxylic (—COOH), amine (—NH2), Phosfonate (—PO4), Sulfonate (—HSO3), Aminoethanethiol, etc. Conducting nanostructures can be made from carbon nanotubes (SWCNT), TiO2 nanotubes or ZnO nanowires.

Conducting nanostructures may be functionalized to facilitate the attachment of photosensitive nanoparticles to the surface of conducting nanostructures. In some embodiments, nanocomposite layer 2940 of photosensitive nanoparticles are attached to conducting nanostructures and dispersed in high mobility polymer such as PVK or P3HT. A precursor of high mobility polymer such as pentacene can be deposited on ITO coated glass substrate by spin coating or other well known solution processing techniques. This layer can be one monolayer or multiple monolayers. The precursor in the nanocomposite layer 2940 is polymerized by heating the films to appropriate temperatures to initiate polymerization of pentacene precursor. If a UV polymerizable precursor is used the polymerization can be achieved by exposing the film to UV from the ITO side 2920. This photovoltaic device can be made by using the process flow shown in FIG. 32. Photovoltaic device built according this embodiment is expected to have high efficiency. In this device electron hole pairs are generated when sunlight is absorbed by the nanoparticles and the resulting electrons are rapidly transported by the conducting nanostructures and the high mobility polymer pentacene to the cathode for collection. This rapid removal of electrons from the electron-hole pairs generated by the nanoparticles eliminates the probability of electron-hole recombination commonly observed in nanoparticle based photovoltaic device devices.

In another embodiment, hole injecting/transporting interface layer or a buffer layer 2930 can be used between ITO 2920 and nanocomposite layer 2940. Alternatively, electron injecting/transporting interface layer 2950 can be used between metal layer 2960 and nanocomposite layer 2940.

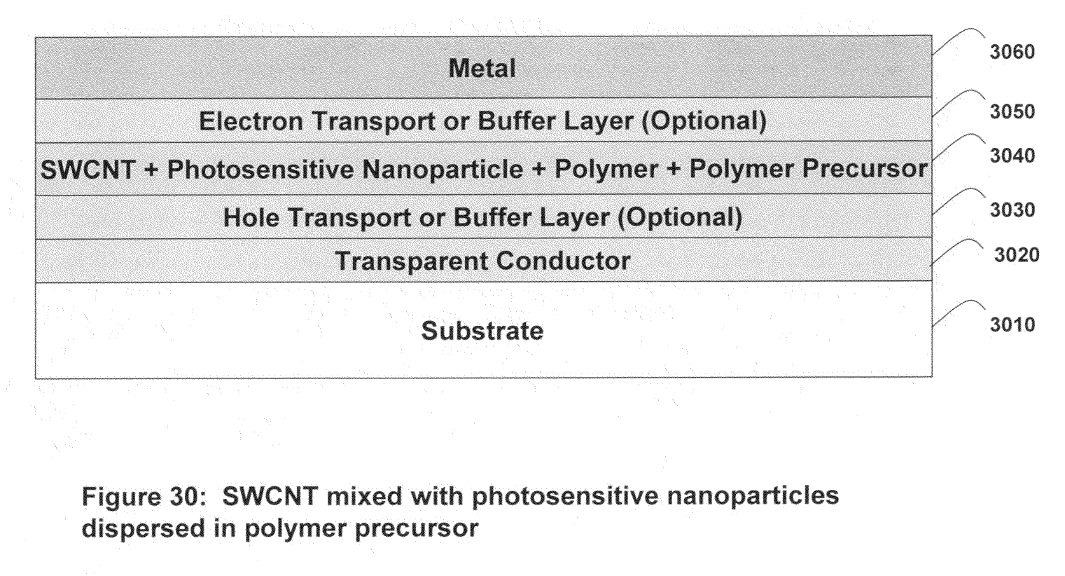

Yet a further embodiment of nanocomposite photovoltaic device is shown in FIG. 30. This photovoltaic device can be built by coating a thin layer of nanocomposite 3040 containing photosensitive nanoparticles and conducting nanostructure dispersed in a precursor of a high mobility polymer such as pentacene on a glass substrate 3010 coated with a transparent conductor 3020 such as ITO followed by the deposition of cathode metal layer 3060. Photosensitive nanoparticles can be made from Group IV, II-IV, II-VI, IV-VI, III-V materials. Examples of photosensitive nanoparticles include Si, Ge, CdSe, PbSe, ZnSe, CdTe, CdS, PbS. Nanoparticle sizes can be varied (for example: 2-10 nm) to obtain a range of bandgaps. These nanoparticles can be prepared by following the methods known in the art. Nanoparticles can be functionalized by following methods known in the art. Functional groups can include carboxylic (—COOH), amine (—NH2), Phosfonate (—PO4), Sulfonate (—HSO3), Aminoethanethiol, etc. Conducting nanostructures can be made from carbon nanotubes (SWCNT), TiO2 nanotubes or ZnO nanowires. The conducting nanostructure can be functionalized to facilitate their dispersal in the precursor of high mobility polymer. Nanocomposite layer 3040 of photosensitive nanoparticles and conducting nanostructures dispersed in precursor of high mobility polymer such as pentacene can be deposited on ITO coated glass substrate by spin coating or other well known solution processing techniques. This layer can be one monolayer or multiple monolayers. Precursor in the nanocomposite layer 3040 is polymerized by heating the films to appropriate temperatures to initiate polymerization of precursor. If a UV polymerizable precursor is used the polymerization can be achieved by exposing the film to UV from the ITO side 3020. Photovoltaic device built according this embodiment is expected to have high efficiency. In this device electron hole pairs are generated when sunlight is absorbed by the nanoparticles and the resulting electrons are rapidly transported by the conducting nanostructures and the high mobility polymer such as pentacene to the cathode for collection. This rapid removal of electrons from the electron-hole pairs generated by the nanoparticles eliminates the probability of electron-hole recombination commonly observed in nanoparticle based photovoltaic device devices. In some embodiments, hole injecting/transporting interface layer or a buffer layer 3030 can be used between ITO 3020 and nanocomposite layer 3040. Alternatively, electron injecting/transporting interface layer 3050 can be used between metal layer 3060 and nanocomposite layer 3040.

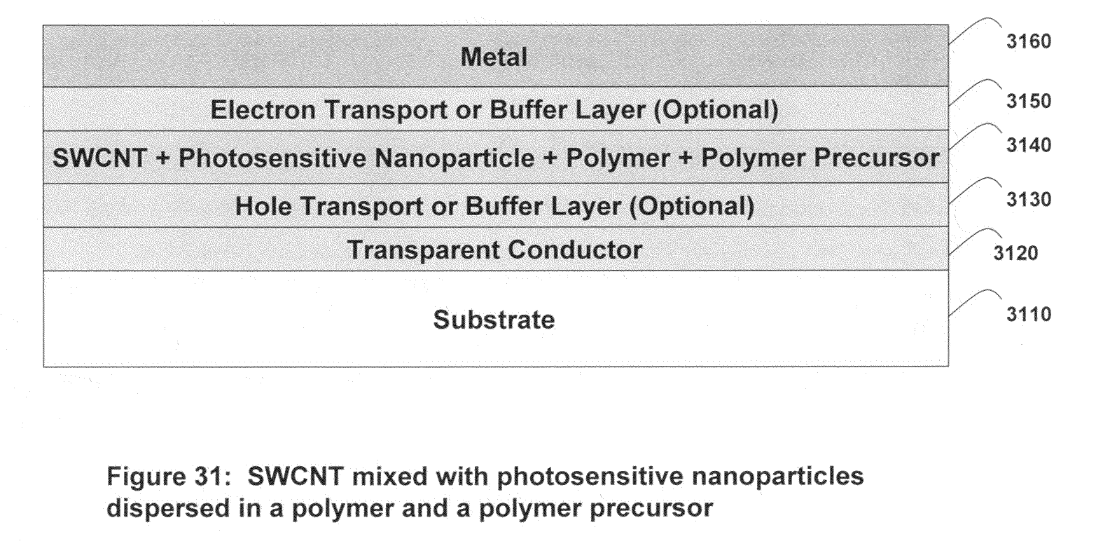

FIG. 31 depicts yet another embodiment of nanocomposite photovoltaic device. This photovoltaic device can be built by coating a nanocomposite layer 3140 comprising photosensitive nanoparticles and conducting nanostructures dispersed in a high mobility polymer such as PVK or P3HT and a precursor of a high mobility polymer such as pentacene 3140 on a glass substrate 3110 coated with a transparent conductor 3120 such as ITO followed by the deposition of cathode metal layer 3160. Photosensitive nanoparticles can be made from Group IV, II-IV, II-VI, IV-VI, III-V materials. Examples of photosensitive nanoparticles include Si, Ge, CdSe, PbSe, ZnSe, CdTe, CdS, PbS. Nanoparticle sizes can be varied (for example: 2-10 nm) to obtain a range of bandgaps. These nanoparticles can be prepared by following the methods known in the art. Nanoparticles can be functionalized by following the methods known in the art. Functional groups can include carboxylic (—COOH), amine (—NH2), Phosfonate (—PO4), Sulfonate (—HSO3), Aminoethanethiol, etc. Conducting nanostructures can be made from carbon nanotubes (SWCNT), TiO₂ nanotubes or ZnO nanowires. Conducting nanostructure can be functionalized to facilitate their dispersion in conducting polymer and precursor of high mobility polymer. Nanocomposite layer 3140 of photosensitive nanoparticles and conducting nanostructures dispersed in high mobility polymer such as PVK or P3HT and a precursor of high mobility polymer such as pentacene can be deposited on ITO coated glass substrate by spin coating or other well known solution processing techniques. This layer can be one monolayer or multiple monolayers. Precursor in the nanocomposite layer 3140 is polymerized by heating the films to appropriate temperatures to initiate polymerization of pentacene precursor. If a UV polymerizable precursor is used the polymerization can be achieved by exposing the film to UV from the ITO side. Photovoltaic device shown in FIG. 31 can be made by using the method steps illustrated in FIG. 32. Photovoltaic device built according this embodiment is expected to have high efficiency. In this device electron hole pairs are generated when sunlight is absorbed by the nanoparticles and the resulting electrons are rapidly transported by the conducting nanostructures and the high mobility polymer pentacene to the cathode for collection. This rapid removal of electrons from the electron-hole pairs generated by the nanoparticles eliminates the probability of electron-hole recombination commonly observed in nanoparticle based photovoltaic device devices.

In a version of this embodiment shown in FIG. 31, hole injecting/transporting interface layer or a buffer layer 3130 can be used between ITO 3120 and nanocomposite layer 3140. Alternatively, electron injecting/transporting interface layer 3150 can be used between metal layer 3160 and nanocomposite layer 3140.

The above embodiments are some examples of the applying the present invention. It will be understood to any one skilled in the art that other transparent conducting materials such as Zinc Oxide, Tin Oxide, Indium Tin Oxide, Indium Zinc Oxide can be used in the above embodiments. It will be understood to any one skilled in the art that the photosensitive nanoparticles can have various shapes—dots, rods, bipods, multipods, wires etc. It will be understood to any one skilled in the art that other conducting nanotube materials can be used in place of carbon nanotubes, TiO₂ nanotubes and ZnO nanotubes described in the embodiments. It will be understood to any one skilled in the art that other heat curable or radiation curable precursors can be used in place of the pentacene precursors. It will be understood to any one skilled in the art that other conducting polymers can be used in place PVK, P3HT and PEDOT. It will be understood to any one skilled in the art that a mixture of conducting and non-conducting polymer can be used in place of conducting polymers PVK, P3HT and PEDOT described in the embodiments.

FIG. 32 illustrates one embodiment of a method which may be utilized to prepare photovoltaic devices according to some embodiments of the present invention. Specifically, a substrate is coated with ITO at step 3210. A buffer layer may optionally be deposited atop the ITO coated substrate at step 3220. The device then undergoes solution coating at step 3240. Optionally, the solution may contain photosensitive nanoparticles, polymer precursor and a polymer, step 3230. A buffer layer may optionally be deposited after solution coating, step 3250. Next, metal is deposited at step 3260, and finally the precursor is polymerized at step 3270. Polymerization may occur by thermal or UV exposure.

The foregoing descriptions of specific embodiments and best mode of the present invention have been presented for purposes of illustration and description only. They are not intended to be exhaustive or to limit the invention to the precise forms disclosed. Specific features of the invention are shown in some drawings and not in others, for purposes of convenience only, and any feature may be combined with other features in accordance with the invention. Steps of the described processes may be reordered or combined, and other steps may be included. The embodiments were chosen and described in order to best explain the principles of the invention and its practical application, to thereby enable others skilled in the art to best utilize the invention and various embodiments with various modifications as are suited to the particular use contemplated. Further variations of the invention will be apparent to one skilled in the art in light of this disclosure and such variations are intended to fall within the scope of the appended claims and their equivalents. The publications referenced above are incorporated herein by reference in their entireties.

I claim:

1. A photovoltaic device, comprising:
a first photoactive layer comprised of a semiconductor material exhibiting absorption of radiation substantially in a visible region of the solar spectrum;
a second photoactive layer comprised of nanostructured material exhibiting absorption of radiation substantially in an IR region of the solar spectrum; and
a recombination layer, disposed between the first and second layers, and configured to promote charge transport between the first and second layers.

2. The photovoltaic device of claim 1 wherein the nanostructured material is a nanocomposite material which comprises hole conducting or electron conducting polymer and complimentary nanoparticles.

3. The photovoltaic device of claim 2 where the recombination layer is a doped layer comprised of a material that conducts charge opposite that of the conducting polymer.

4. The photovoltaic device of claim 2 where the recombination layer is a doped layer comprised of a material that conducts charge opposite that of the nanoparticle.

5. The photovoltaic device of claim 2 where the recombination layer further comprises a metal layer coupled to doped layer.

6. The photovoltaic device of claim 2 wherein the recombination layer further comprises an insulating layer of coupled to doped layer.

7. The photovoltaic device of claim 1 wherein the nanostructured material is comprised of any one or more of: semiconducting dots, rods or multipods.

8. The photovoltaic device of claim 2 wherein the nanocomposite material is comprised of one or more nanoparticles dispersed in a polymer.

9. The photovoltaic device of claim 7 wherein the one or more nanoparticles are comprised of any one or more of: PbSe, PbS, CdHgTe, Si or SiGe.

10. The photovoltaic device of claim 8 wherein the one or more nanoparticles are comprised of any one or more of: PbSe, PbS, CdHgTe, Si or SiGe.

11. The photovoltaic device of claim 8 wherein the polymer is comprised of any one or more of: P3HT, pentacene or MEH-PPV.

12. The photovoltaic device of claim 1 wherein the nanostructured material is comprised of a mixture of photosensitive nanoparticles and conductive nanoparticles.

13. The photovoltaic device of claim 12 wherein one or both of the photosensitive and conductive nanoparticles are functionalized.

14. The photovoltaic device of claim 12 wherein the conductive nanoparticles are comprised of any one or more of: single wall carbon nanotubes (SWCNT), TiO₂ nanotubes, or ZnO nanowires.

15. The photovoltaic device of claim 12 wherein the photosensitive nanoparticles are comprised of any one or more of: CdSe, ZnSe, PbSe, InP, Si, Ge, SiGe, or Group III-V materials.

16. The photovoltaic device of claim 1 wherein the second layer comprises one or more inorganic nanoparticles dispersed in a hole conducting polymer, and the recombination layer further comprises:
an N+ doped layer; and
a metal layer coupled to said N+ doped layer.

17. The photovoltaic device of claim 1 wherein the first photoactive layer is comprised of any one of: amorphous silicon, single-crystalline silicon, poly-crystalline silicon, microcrystalline silicon, nanocrystalline silicon, CdTe, cooper indium gallium diselinide (CIGS), or Group III-V semiconductor material.

18. The photovoltaic device of claim 1 wherein the first photoactive layer is comprised of an organic material which is hole conducting or electron conducting.

19. The photovoltaic device of claim 1 wherein the first photoactive layer is comprised on any one or more of: P3HT, P3OT, MEH-PPV, PCBM, CuPe, PCTBI or C60.

20. The photovoltaic device of claim 1 wherein the first photoactive layer comprises a P-I-N semiconductor or a P-N semiconductor.

21. The photovoltaic device of claim 1 wherein the first photoactive layer is comprised of multiple layers, each layer being configured to absorb a particular range of the visible spectrum.

22. The photovoltaic device of claim 21 further comprising: one or more recombination layers disposed between one or more of the multiple layers, said recombination layers configured to promote charge transport across the multiple layers.

23. The photovoltaic device of claim 1 wherein the second photoactive layer is comprised of multiple layers, each layer being configured to absorb a particular range of the IR spectrum.

24. The photovoltaic device of claim 23 further comprising: one or more recombination layers disposed between one or more of the multiple layers, said recombination layers configured to promote charge transport across the multiple layers.

25. The photovoltaic device of claim 1 further comprising: a top photoactive layer, disposed above the first layer, the top photoactive layer comprises material exhibiting absorption of radiation substantially in an UV region of the solar spectrum.

26. The photovoltaic device of claim 25 further comprising a second recombination layer, disposed between the first and top layers, and configured to promote charge transport between the top and first layer.

27. The photovoltaic device of claim 25 wherein the top photoactive layer is comprised of one or more nanoparticles.

28. The photovoltaic device of claim 25 wherein the top photoactive layer is comprised of a one or more nanoparticles dispersed in a polymer matrix.

29. The photovoltaic device of claim 28 wherein the one or more nanoparticles are comprised of any one or more of: ZnSe or CdZnTe.

30. A photovoltaic device, comprising:
a first photoactive layer;
a top photoactive layer disposed above the first layer, said top photoactive layer comprised of a material exhibiting a bandgap greater than the band gap of the first layer; and
a bottom photoactive layer disposed below the first layer, said bottom photoactive layer comprised of a material exhibiting a bandgap lower than the band gap of the first layer.

31. The photovoltaic device of claim 30 wherein the top photoactive layer exhibits a bandgap of 2 ev and greater.

32. The photovoltaic device of claim 30 wherein the bottom photoactive layer exhibits a bandgap of 1.2 ev and lower.

33. A photovoltaic device comprising:
a first photoactive layer comprised of a semiconductor material exhibiting absorption of radiation substantially in a visible region of the solar spectrum;
a top photoactive layer comprised of one or more nanoparticles exhibiting absorption of radiation substantially in an UV region of the solar spectrum; and
a recombination layer, disposed between the first and top layers, and configured to promote charge transport between the first and top layers.

34. The photovoltaic device of claim 33 wherein the recombination layer comprised of a P+ doped layer.

35. The photovoltaic device of claim 33 wherein the first photoactive layer comprises a P-I-N semiconductor.

36. The photovoltaic device of claim 33 wherein the one or more nanoparticles are dispersed in a polymer matrix.

37. A photovoltaic device, comprising:
a first photoactive layer comprised of semiconductor material exhibiting absorption of radiation substantially in a visible region of the solar spectrum;
a top photoactive layer comprised of nanostructured material exhibiting absorption of radiation substantially in an UV region of the solar spectrum;
a recombination layer, disposed between the first and top layers, and configured to promote charge transport between the first and top layers;
a bottom photoactive layer comprised of nanostructured material exhibiting absorption of radiation substantially in an IR region of the solar spectrum; and
a second recombination layer, disposed between the first and bottom layers, and configured to promote charge transport between the first and bottom layers.
